(19) United States
(12) Patent Application Publication
(10) Pub. No.: US 2013/0319525 A1
(43) Pub. Date: Dec. 5, 2013

(54) BIAXIALLY STRETCHED POLYESTER FILM, METHOD FOR PRODUCING THE SAME, BACK SHEET FOR SOLAR CELL, AND SOLAR CELL MODULE

(71) Applicant: FUJIFILM Corporation, Tokyo (JP)

(72) Inventor: Shinichi Nakai, Kanagawa (JP)

(73) Assignee: FUJIFILM Corporation, Tokyo (JP)

(21) Appl. No.: 13/965,747

(22) Filed: Aug. 13, 2013

Related U.S. Application Data
(63) Continuation of application No. PCT/JP2012/053012, filed on Feb. 9, 2012.

(30) Foreign Application Priority Data
Feb. 15, 2011 (JP) 2011-030278
Jul. 27, 2011 (JP) 2011-164839

(51) Int. Cl. H01L 31/048

(52) U.S. Cl. CPC H01L 31/0487
USPC 136/259; 428/220; 264/210.7

(57) ABSTRACT

A biaxially stretched polyester film having reduced occurrences of scratches and having superior hydrolysis resistance as compared with conventional polyester films is provided. The polyester film has: a film width of 1 m or more; an intrinsic viscosity (IV) of 0.70 dL/g or greater; a pre-peak temperature measured by differential scanning calorimetry (DSC) of from 160° C. to 210° C.; and a variation in a degree of crystallinity in a film width direction of from 0.3% to 5.0%.

### CROSS-REFERENCE TO RELATED APPLICATIONS

This application is a continuation application of International Application No. PCT/JP2012/053012, filed Feb. 9, 2012, the disclosure of which is incorporated herein by reference in its entirety. Further, this application claims priority from Japanese Patent Application No. 2011-030278, filed Feb. 15, 2011, and Japanese Patent Application No. 2011-164839, filed Jul. 27, 2011, the disclosures of which are incorporated herein by reference in their entirety.

### TECHNICAL FIELD

The present invention relates to a biaxially stretched polyester film, a method for producing the film, a back sheet for a solar cell, and a solar cell module.

### BACKGROUND ART

Polyesters have been applied to a variety of applications such as electrical insulation applications and optical applications. Among them, as for an electrical insulation application, attention has been paid in recent years particularly to an application in solar cells such as a sheet for protecting the back surface of a solar cell (so-called a back sheet).

On the other hand, polyesters usually have many carboxyl groups or hydroxyl groups present on the surface, so that under environmental conditions where moisture is present, polyesters are likely to undergo a hydrolysis reaction and tend to deteriorate with the passage of time. For example, the installation environment in which solar cell modules are generally used is an environment that is always exposed to the weather, such as outdoors, and since solar cell modules are exposed to conditions in which hydrolysis reactions may easily proceed, in the case where a polyester is applied to a solar cell application, hydrolyzability of the polyester being suppressed is one of important characteristics.

Furthermore, in general, when it is intended to produce a polyester film having a desired thickness by stretching a polyester in a sheet form that has been cooled after melt extrusion, so-called thermal fixing, in which heat is applied at a relatively high temperature after stretching to cause crystallization, is carried out. This thermal fixing is usually carried out in a temperature range of about 230° C. to 240° C. in view of increasing the degree of crystallinity and eliminating residual strain. However, from the viewpoint of increasing the hydrolysis resistance, it is preferable that the temperature at the time of thermal fixing be low. Furthermore, in the production process of polyester films, wrinkles, scratches and the like tend to easily occur for various causes at the time of heating and conveyance.

Regarding technologies related to the circumstances described above, from the viewpoint of dimensional stabilization, a laminate in which a layer containing a metal or a metallic oxide is provided on a polyester film has been disclosed (see, for example, Japanese Patent Application Laid-Open (JP-A) No. 2010-52416).

Furthermore, a stretched polyester film having a maximum value of the amount of change in specific gravity in the film width direction of 0.13% or less and thermal shrinkage ratios in the longitudinal direction and the width direction of 3% or less, has been disclosed (see, for example, JP-A No. 2004-18784). It is disclosed that the bowing phenomenon in which when a film that has been stretched in the longitudinal direction is stretched in the width direction and thermally fixed, the film is deformed in a bow shape in the film longitudinal direction, is suppressed. The bowing phenomenon is a factor that disturbs uniformity in the film width direction.

### SUMMARY OF INVENTION

### Technical Problem

It can be said that in order to increase hydrolysis resistance of a polyester, decreasing the heating temperature at the time of thermal fixing works effectively. However, for example, when the temperature at the time of thermal fixing (thermal fixing temperature) is adjusted to a temperature range decreased to, for example, 210° C. or lower, a polyester film is such that on the occasion of drying or film bonding during the process, the central portion is prone to become loose compared with edge portions in the film width direction, and due to the difference in looseness between the edge portions and the central portion, wrinkles, scratches and the like may easily occur at the time of conveyance.

Wrinkles and scratches that are formed in a polyester tend to impair the hydrolysis resistance, and in order to realize long-term durability at a level higher than the conventional level, it is inevitable to establish a method in which wrinkles and scratches do not easily occur at the time of conveyance.

The present invention has been made in view of the circumstances described above, and it is an object of the present invention to provide a biaxially stretched polyester film having reduced occurrences of scratches and having superior hydrolysis resistance as compared with conventional polyester films, a method for producing the polyester film, a back sheet for a solar cell having excellent long-term durability performance, and a solar cell module that can give stable power generation performance over a long time period. Thus, achieving the object is a problem to be solved by the present invention.

### Solution to Problem

It has been found that the cause of the central portion being prone to become loose compared with edge portions in the width direction of a film lies in the variation of a thermal shrinkage ratio in the width direction, which is associated with variation in the degree of crystallinity in the film width direction, and the present invention has been achieved based on such findings.

Specific means for achieving the object are as follows.

<1> A biaxially stretched polyester film, having:

a film width of 1 m or more;

an intrinsic viscosity (IV) of 0.70 dL/g or greater;

a pre-peak temperature measured by differential scanning calorimetry (DSC) of from 160° C. to 210° C.; and

a variation in a degree of crystallinity in a film width direction of from 0.3% to 5.0%.

<2> The biaxially stretched polyester film according to <1>, having an intrinsic viscosity (IV) of 0.75 dL/g or greater.

<3> The biaxially stretched polyester film according to <1> or <2>, wherein a variation in a thermal shrinkage ratio A in the film width direction and a variation in a thermal shrinkage ratio B in the film width direction are respectively from 0.03% to 0.50%, and wherein the thermal shrinkage ratio A is a thermal shrinkage ratio in a direction perpendicular to the film width direction, and the thermal shrinkage ratio B is a thermal shrinkage ratio in a direction parallel to the film width direction.

<4> The biaxially stretched polyester film according to any one of <1> to <3>, having a thickness of from 180 μm to 350 μm.

<5> The biaxially stretched polyester film according to any one of <1> to <4>, comprising a constituent unit derived from a polyfunctional monomer in which a sum total of a number of a carboxylic group and a number of a hydroxyl group is 3 or greater.

<6> The biaxially stretched polyester film according to any one of <1> to <5>, comprising a constituent unit derived from a polyfunctional monomer in which a sum total of a number of a carboxylic group and a number of a hydroxyl group is 3 or greater, wherein a content ratio of the constituent unit derived from the polyfunctional monomer is from 0.005% by mole to 2.5% by mole relative to all constituent units in the polyester.

<7> The biaxially stretched polyester film according to any one of <1> to <6>, comprising a structural moiety derived from a terminal blocking agent selected from an oxazoline compound, a carbodiimide compound, or an epoxy compound.

<8> The biaxially stretched polyester film according to <7>, wherein a content ratio of the structural moiety derived from the terminal blocking agent is from 0.1% by mass to 5% by mass relative to a total mass of the polyester.

<9> A method for producing a biaxially stretched polyester film, the method comprising:

molding a polyester film by melt extruding a polyester raw material resin into sheet form, and cooling the resin on a casting drum;

longitudinally stretching the molded polyester film in a longitudinal direction; and

transversely stretching the polyester film after the longitudinal stretching in a width direction perpendicular to the longitudinal direction,

wherein the transverse stretching comprises:

preheating the polyester film after the longitudinal stretching to a temperature at which stretching can be carried out;

transversely stretching the preheated polyester film by applying tension to the film in the width direction perpendicular to the longitudinal direction;

thermally fixing the polyester film after the longitudinal stretching and the transverse stretching have been carried out, by heating the polyester film so as to have a variation in a maximum film surface temperature in the width direction of from 0.5° C. to 5.0° C., while controlling the maximum film surface temperature of the polyester film in a range of from 160° C. to 210° C., to crystallize the polyester film;

relaxing a tension of the thermally fixed polyester film by heating the polyester film; and

cooling the polyester film after the relaxing.

<10> The method for producing a biaxially stretched polyester film according to <9>, wherein the thermal fixing comprises selectively heating edge portions in the width direction of the polyester film from at least one side of the polyester film.

<11> The method for producing a biaxially stretched polyester film according to <9> or <10>, wherein a thickness of the polyester film after the cooling is from 180 μm to 350 μm, and wherein the thermal fixing comprises heating the polyester film such that a heated surface of the polyester film that is heated is a surface that has been brought into contact with the casting drum in the molding, and a surface temperature of the heated surface immediately after the heating is higher than a surface temperature of a non-heated surface on a side opposite to the heated surface by from 0.5° C. to 5.0° C.

<12> The method for producing a biaxially stretched polyester film according to any one of <9> to <11>, wherein the thermal fixing comprises radiation heating of edge portions in the width direction of the polyester film using a heater.

<13> The method for producing a biaxially stretched polyester film according to any one of <9> to <12>, wherein in the thermal fixing, a retention time in a heated state is from 5 seconds to 50 seconds.

<14> The method for producing a biaxially stretched polyester film according to any one of <9> to <13>, wherein at least one of the preheating, the transverse stretching of the preheated polyester film, or the relaxing comprises radiation heating of edge portions in the width direction of the polyester film using a heater.

<15> The method for producing a biaxially stretched polyester film according to any one of <9> to <14>, wherein the polyester raw material resin contains, as a copolymerization component, a polyfunctional monomer in which a sum total of a number of a carboxylic group and a number of a hydroxyl group is 3 or greater.

<16> The method for producing a biaxially stretched polyester film according to any one of <9> to <15>, wherein the polyester raw material resin contains, as a copolymerization component, a polyfunctional monomer in which a sum total of a number of a carboxylic group and a number of a hydroxyl group is 3 or greater, and a content ratio of a constituent unit derived from the polyfunctional monomer in the polyester raw material resin is from 0.005% by mole to 2.5% by mole relative to all constituent units in the polyester raw material resin.

<17> The method for producing a biaxially stretched polyester film according to any one of <9> to <16>, wherein the molding comprises incorporating a terminal blocking agent selected from an oxazoline compound, a carbodiimide compound or an epoxy compound into the polyester raw material resin, and melt extruding the polyester raw material resin that has reacted with the terminal blocking agent as a result of melt kneading.

<18> The method for producing a biaxially stretched polyester film according to <17>, wherein a content of the terminal blocking agent is from 0.1% by mass to 5% by mass relative to a total mass of the polyester raw material resin.

<19> A back sheet for a solar cell, comprising the biaxially stretched polyester film according to any one of <1> to <8>.

<20> A solar cell module comprising: a transparent substrate through which sunlight enters; a solar cell device disposed on one side of the substrate; and the back sheet for a solar cell according to <19> that is disposed on a side of the solar cell device opposite to a side thereof on which the substrate is disposed.

### Advantageous Effects of invention

According to the present invention, it is possible to provide a biaxially stretched polyester film having reduced occurrences of scratches and having superior hydrolysis resistance as compared with conventional polyester films, and a method for producing the polyester film.

Further, according to the present invention, it is possible to provide a back sheet for a solar cell having excellent long-term durability performance, and a solar cell module that can give stable power generation performance over a long time period.

### BRIEF DESCRIPTION OF DRAWINGS

FIG. 1 is a top view illustrating an example of a biaxial stretching machine from the top side.

### DESCRIPTION OF EMBODIMENTS

Hereinafter, the polyester film of the present invention and a method for producing the same will be described in detail, and based on that description, the back sheet for a solar cell and the solar cell module of the present invention will also be described.

<Polyester Film>

The polyester film of the present invention is configured to have a film width of 1 m or greater, an intrinsic viscosity (IV) value of 0.70 dL/g or greater, a pre-peak temperature as measured by differential scanning calorimetry (DSC; hereinafter, may be simply described as “DSC”) of from 160° C. to 210° C., and a variation in the degree of crystallinity in the film width direction of from 0.3% to 5.0%.

The hydrolysis resistance of polyester films have been insufficient because the thermal fixing temperature in the case of thermal fixing by performing crystallization after stretching is generally as high as about 230° C. to 240° C. But, from the viewpoint of enhancing hydrolysis resistance, it is effective to control the thermal fixing temperature at the time of thermal fixing to a film temperature of 160° C. to 210° C. However, if the thermal fixing temperature is set to a temperature lower than or equal to 210° C., the central portion of a polyester film is likely to become loose compared with the edge portions in the width direction during the production process, so that there is an inconvenience that due to the difference in looseness between the edge portions and the central portion, wrinkles and scratches may easily occur at the time of conveyance.

It is speculated that a factor by which the central portion of a film is prone to become loose compared with the edge portions in the width direction during the production process, lies in the variation in the degree of crystallinity in the width direction, that is, the variation in the thermal shrinkage ratio in the width direction that is caused by the lower degree of crystallinity at the edge portions compared with the degree of crystallinity at the central portion of the film. Specifically, the thermal shrinkage ratio at the central portion becomes smaller compared with the edge portions of the film. As such, when there is a difference in the thermal shrinkage ratio in the film width direction, since the central portion of the film can shrink with more difficulties as compared with the edge portions, the central portion of the film becomes loose compared with the edge portions. Thus, in the present invention, when the intrinsic viscosity (IV) of a polyester is adjusted to 0.70 dL/g or greater, and the variation in the degree of crystallinity in the width direction of a polyester film (=degree of crystallinity at the central portion of the film−degree of crystallinity at the edge portions of the film) is adjusted to from 0.3% to 5.0%, as the IV is increased, crystallization can be delayed, and the variation in the degree of crystallinity is suppressed to a low level. Accordingly, the hydrolysis resistance is enhanced, and a difference in looseness between the edge portions in the width direction and the central portion of the film does not easily occur during the production process. Thereby, the occurrence of wrinkles or scratches in the polyester film during conveyance is suppressed.

In addition, the production process described above may be, for example, a drying process after film formation; a bonding process of heating two or more kinds of films that require bonding to a predetermined temperature while conveying the films on a metal roll, applying an adhesive or a tacky adhesive on the film, and bonding the films; or the like.

Furthermore, as described above, the thermal fixing temperature is usually considered to be 230° C. to 240° C.; however, when a plot is made with the thermal fixing temperature on the horizontal axis and the degree of crystallinity (the degree of crystallinity achieved when the film is retained for 20 seconds at the relevant temperature) on the vertical axis, the change in the degree of crystallinity when the thermal fixing temperature is 160° C. to 210° C. is larger than the change in the degree of crystallinity when the thermal fixing temperature is 230° C. to 240° C., and the temperature dependency is large. On the other hand, on a tenter, under the influence of heat escaping from the clips, the film temperature at the edge portions tends to become considerably lower as compared with the central portion of the film. Under that influence, the thermal fixing temperature at the edge portions is lowered as compared with the central portion in the film width direction. Therefore, when the thermal fixing temperature is adjusted to a low temperature range of 160° C. to 210° C., since the influence of the difference in the thermal fixing temperature between the central portion and the edge portions in the film width direction is also likely to appear as the difference in the degree of crystallinity, the variation in the degree of crystallinity in the film width direction tends to increase (the degree of crystallinity at the edge portions becomes smaller than that at the central portion). That is, when it is intended to increase the hydrolysis resistance by lowering the thermal fixing temperature, the change in the degree of crystallinity within the film plane increases; however, when the IV value is adjusted to 0.70 or greater, since the molecular chains of polyester cannot easily move around, the occurrence of crystallization can be made more difficult. Thereby, while the polyester film is molded into a relatively thick film, the variation in the degree of crystallinity in the film width direction is suppressed, the occurrence of damages such as scratches is prevented, and excellent hydrolysis resistance is obtained.

In the polyester film of the present invention, the intrinsic viscosity (IV) is adjusted to a relatively high range of 0.70 dL/g or greater. As described above, if the IV is less than 0.70 dL/g, crystallization proceeds relatively easily, and damages easily occur on the film surface. Therefore, even if the heating temperature at the time of thermal fixing is lowered to, for example, 210° C. or lower in order to enhance the hydrolysis resistance, satisfactory hydrolysis resistance may not be obtained.

From the viewpoint of improving weather resistance by further increasing the hydrolysis resistance, the IV value is preferably 0.75 dL/g or greater, more preferably 0.78 dL/g or greater, and even more preferably 0.80 dL/g or greater. Specifically, the IV value is preferably from 0.70 dL/g to 0.90 dL/g, more preferably from 0.75 dL/g to 0.90 dL/g, even more preferably from 0.75 dL/g to 0.85 dL/g, and most preferably from 0.78 dL/g to 0.85 dL/g.

Furthermore, the pre-peak temperature obtainable when an analysis is carried out by differential scanning calorimetry (DSC) is set in the range of from 160° C. to 210° C. The “pre-peak temperature” of DSC as used herein is the temperature of a peak that initially appears when a DSC analysis is made, and generally, this temperature corresponds to the maximum reached film surface temperature (thermal fixing temperature) of a polyester film at the time of thermal fixing.

If the pre-peak temperature of DSC is lower than 160° C., the thermal fixing temperature is so low that thermal fixing cannot be carried out sufficiently, the variation in the degree of crystallinity increases, and the difference in the thermal shrinkage ratio increases. That is, looseness at the central portion of the film increases so that damages occur. Furthermore, if the pre-peak temperature of DSC is higher than 210° C., the IV value increases, but the hydrolysis resistance decreases, and the film deteriorates in view of the durability performance over a long time period.

For the reasons such as described above, the pre-peak temperature of DSC is more preferably from 170° C. to 200° C., and even more preferably from 175° C. to 195° C.

The pre-peak temperature of DSC is a value that is determined by a conventional method in differential scanning calorimetry.

Next, the variation in the degree of crystallinity in the film width direction is set in the range of from 0.3% to 5.0%. A change in the degree of crystallinity brings about a change in the thermal shrinkage ratio, and the degree of crystallinity at the central portion of the film tends to become higher as compared with the degree of crystallinity at the film edge portions. As a result, in a polyester film, the thermal shrinkage ratio at the central portion in the width direction becomes smaller than that at the edge portions. Therefore, if the variation in the degree of crystallinity is less than 0.3%, since looseness at the central portion of the film almost disappears, too much tension is applied to the central portion of the film, and wrinkles may easily occur at the time of conveyance. Furthermore, if the variation in the degree of crystallinity exceeds 5.0%, the central portion in the width direction of the film becomes significantly loose, and due to the difference in looseness between the edge portions and the central portion in the width direction, wrinkles, scratches and the like may easily occur at the time of conveyance. If damages and the like occur on the film surface, weather resistance is impaired.

For the reasons described above, the variation in the degree of crystallinity is preferably from 0.5% to 3.0%, more preferably from 0.6% to 1.5%, and even more preferably from 0.7% to 1.3%.

The variation in the degree of crystallinity in the film width direction is calculated by cutting out specimens from three sites in total, namely, one site in the central portion and two sites in both the edge portions, over the entire film width in the width direction that is perpendicular to the film longitudinal direction, measuring the degrees of crystallinity, and subtracting a smaller degree of crystallinity between the degree of crystallinity values of both the edge portions from the degree of crystallinity of the central portion.

The degree of crystallinity is a value calculated from the density of the film. That is, it is the degree of crystallinity Xc (%) derived by the following calculation formula by using the density X (g/cm³) of the film, the density Y (g/cm³) at a degree of crystallinity of 0%, and the density Z (g/cm³) at a degree of crystallinity of 100%. The measurement of density can be carried out according to JIS K7112.

Xc={Z×(X−Y)}/{X×(Z−Y)}×100

The variation in the degree of crystallinity such as described above is likely to occur significantly when the length of the film width is 1 m or more. If the film is large-sized with a length of the film width of 1 m or more, while the temperature change at the edge portions that are gripped by clips or the like is large, a temperature change does not easily occur in the vicinity of the center. Therefore, the difference in the degree of crystallinity between the vicinity of the center and the edge portions becomes larger, and the degree of crystallinity in the vicinity of the center further increases, so that the central portion is more likely to become loose.

Furthermore, the thermal shrinkage ratio (heating conditions: heated for 30 minutes at 150° C.) of the polyester film of the present invention is preferably 2.0% or less. As will be described below, the thermal shrinkage ratio can be adjusted in the range described above by controlling the heating temperature in the various processes of thermal fixing and/or thermal relaxation (T_{thermal fixing} and/or T_{thermal relaxation}) in a transverse stretching process.

Since a polyester generally has a larger coefficient of thermal expansion or a larger coefficient of hygroscopic expansion as compared with glass, there is a tendency that stress is easily exerted during changes in temperature and humidity, and this easily leads to cracking or delamination. However, when the thermal shrinkage ratio is in the range described above, detachment of a functional layer or sheet attached to a polyester film, or cracking of a layer formed by being applied on a polyester film can be prevented.

Above all, the thermal shrinkage ratio is more preferably 1.0% or less, and even more preferably 0.5% or less.

Furthermore, the polyester film of the present invention is preferably such that in regard to the film width direction [in the case of producing a long film by stretching or the like while conveying the film, a direction (TD direction) perpendicular to the conveyance direction (MD direction)], the variation in the thermal shrinkage ratio in a direction perpendicular to the film width direction (MD direction at the time of production) and the variation in the thermal shrinkage ratio in a direction parallel to the film width direction (TD direction at the time of production) are both in the range of from 0.03% to 0.50%. When the variation in the thermal shrinkage ratio is 0.03% or more, it is advantageous in view of wrinkles at the time of conveyance. Furthermore, when the variation in the thermal shrinkage ratio is 0.50% or less, the difference in looseness in the film width direction is suppressed, and the occurrence of wrinkles, scratches and the like at the time of conveyance caused by the difference in looseness can be prevented.

The variation in thermal shrinkage ratio can be adjusted by regulating the variation in the degree of crystallinity in the range of from 0.3% to 5.0%.

From the reasons described above, the variation in thermal shrinkage ratio is more preferably in the range of from 0.04% to 0.30%, even more preferably in the range of from 0.04% to 0.10%, and most preferably in the range of from 0.04% to 0.08%.

The thermal shrinkage ratio according to the present invention is the shrinkage ratio of a polyester film before and after a treatment for 30 minutes at 150° C. (unit %=(film length before treatment−film length after treatment)/film length before treatment×100). The thermal shrinkage ratio has two kinds of values depending on whether the expansion and contraction in the MD direction should be considered, or whether the expansion and contraction in the TD direction should be considered, as the shrinkage amount (length of expansion and contraction) at a site of measurement in the film width direction.

The variation in the thermal shrinkage ratio in the film width direction is calculated by cutting out specimens from three sites in total, namely, one site in the central portion and two sites in both the edge portions, over the entire width of the film in the width direction that is perpendicular to the film longitudinal direction (MD direction at the time of production), measuring thermal shrinkage ratios, subtracting the thermal shrinkage ratio, which has a larger difference from the thermal shrinkage ratio of the central portion between the thermal shrinkage ratios of both the edge portions, from the thermal shrinkage ratio of the central portion, and calculating the absolute value thereof. At this time, two kinds of variations in the MD direction and the TD direction can be respectively determined, depending on the direction in which the shrinkage amount is measured.

The thickness of the polyester film of the present invention is preferably in the range of from 180 μm to 350 μm. When the polyester film is formed to be relatively thick with the thickness being in the range described above, a temperature distribution is likely to occur in the film thickness direction, and variation in the degree of crystallinity is likely to occur. However, in the present invention, the variation in the degree of crystallinity is suppressed, the occurrence of damages is prevented, and the hydrolysis resistance can be more effectively enhanced.

From the reasons as described above, the thickness is more preferably in the range of from 200 μm to 320 μm, and even more preferably in the range of from 200 μm to 290 μm.

The amount of terminal carboxyl groups (amount of terminal COOH; AV) of the polyester film of the present invention is preferably from 5 eq/ton to 21 eq/ton. The amount of terminal COOH is more preferably from 6 eq/ton to 20 eq/ton, and even more preferably from 7 eq/ton to 19 eq/ton.

Meanwhile, in the present specification, the unit “eq/ton” represents the molar equivalent per ton.

AV is the value obtained by completely dissolving a polyester in a mixed solution of benzyl alcohol/chloroform (=⅔; volume ratio), titrating the solution with a reference liquid (0.025 N KOH-methanol mixed solution) using Phenol Red as an indicator, and calculating the value from the titer.

The polyester film of the present invention is synthesized by copolymerizing a dicarboxylic acid component and a diol component. The details of the dicarboxylic acid component and the diol component will be described below. Furthermore, the polyester film of the present invention preferably contains a constituent unit derived from a polyfunctional monomer in which the sum total (a+b) of the number of a carboxylic group (a) and the number of a hydroxyl group (b) is 3 or greater (hereinafter, also referred to as “polyfunctional monomer of trifunctionality or higher functionality”, or simply as “polyfunctional monomer”).

The polyester film of the present invention can be obtained by, as will be described below, for example, subjecting (A) a dicarboxylic acid component and (B) a diol component to an esterification reaction and/or a transesterification reaction by a well known method, and more preferably, can be obtained by copolymerizing these with a polyfunctional monomer of trifunctionality or higher functionality. The details such as examples and preferred embodiments of the dicarboxylic acid component, the diol component, the polyfunctional monomer and the like are as will be described below.

˜Constituent Unit Derived from Polyfunctional Monomer˜

Examples of the constituent unit derived from a polyfunctional monomer in which the sum total (a+b) of the number of a carboxylic group (a) and the number of a hydroxyl group (b) is 3 or greater, include, as will be described below, a carboxylic acid in which the number of a carboxylic group (a) is 3 or greater, ester derivatives and acid anhydrides thereof; a polyfunctional monomer in which the number of hydroxyl group (b) is 3 or greater; and “an oxy acid which has both a hydroxyl group and a carboxylic group in one molecule, and in which the sum total (a+b) of the number of a carboxylic group (a) and the number of a hydroxyl group (b) is 3 or greater”. The details of these examples and preferred embodiments are as will be described below.

Furthermore, compounds obtained by adding an oxy acid such as 1-lactide, d-lactide or hydroxybenzoic acid, a derivative thereof, plural oxy acids linked together, and the like to the carboxy terminal of the carboxylic acid or the carboxy terminal of the “polyfunctional monomer having both a hydroxyl group and a carboxylic group in one molecule”, are also suitable.

These may be used singly, or if necessary, plural kinds may also be used in combination.

For the polyester film of the present invention, the content ratio of the constituent unit derived from a polyfunctional monomer of trifunctionality or higher functionality is preferably from 0.005% by mole to 2.5% by mole, based on all the constituent units in the polyester film. The content ratio of the constituent unit derived from a polyfunctional monomer is more preferably from 0.020% by mole to 1% by mole, even more preferably from 0.025% by mole to 1% by mole, still more preferably from 0.035% by mole to 0.5% by mole, particularly preferably from 0.05% by mole to 0.5% by mole, and most preferably from 0.1% by mole to 0.25% by mole.

When a constituent unit derived from a polyfunctional monomer of trifunctionality or higher functionality is present in the polyester film, a structure in which polyester molecular chains are branched from the constituent unit derived from a polyfunctional monomer of trifunctionality or higher functionality is obtained, and entanglement between the polyester molecules can be prompted. As a result, even if polyester molecules are exposed to a high temperature high humidity environment and are hydrolyzed so that the molecular weight is decreased, since entanglement between the polyester molecules has been formed, embrittlement of a polyester film is suppressed, and superior weather resistance is obtained. Furthermore, such entanglement is also effective in the suppression of thermal shrinkage. This is speculated to be because, since the mobility of polyester molecules is decreased as a result of the entanglement of the polyester molecules, even if the molecules try to shrink under heat, the molecules cannot shrink, and thermal shrinkage of the polyester film is suppressed.

Also, when the polymer contains a polyfunctional monomer of trifunctionality or higher functionality as a constituent unit, the functional groups that have not been used in polycondensation after the esterification reaction, are subjected to hydrogen bonding and covalent bonding with the components in a coating layer that is formed by being applied on the polyester film, and thereby the adhesiveness between the coating layer and the polyester film is maintained more satisfactorily, so that the occurrence of detachment can be effectively prevented. A polyester film that is used in a back sheet for a solar cell is closely adhered to a sealing agent such as EVA after a coating layer such as an easy adhesion layer is applied and formed thereon; however, even in the case where the polyester film is subjected to an environment that is exposed to weather for a long time, such as outdoors, satisfactory adhesiveness that is not easily detached is obtained.

Therefore, when the content ratio of the constituent unit derived from a polyfunctional monomer of trifunctionality or higher functionality is 0.005% by mole or more, weather resistance, low thermal shrinkage property, and the adhesive power to a coating layer that is formed by being applied on a polyester film can be more easily enhanced. Also, when the content ratio of the constituent unit derived from a polyfunctional monomer of trifunctionality or higher functionality is 2.5% by mole or less, the difficulty in crystal formation, which is caused by the bulky constituent unit derived from a polyfunctional monomer of trifunctionality or higher functionality, is suppressed. As a result, the formation of less migrating components that are formed through crystals is prompted, and a decrease in hydrolyzability can be suppressed. Furthermore, since the amount of fine surface asperities at the film surface increases due to the bulkiness of the constituent unit derived from a polyfunctional monomer of trifunctionality or higher functionality, an anchor effect can be easily exhibited, and the adhesion between the polyester film and a coating layer that is formed by being applied on the film is enhanced. Furthermore, due to this bulkiness, increase in free volumes (gaps between molecules) is suppressed, and the thermal shrinkage occurring as a result of polyester molecules slipping through the large free volumes can be suppressed. Also, a decrease in the glass transition temperature (Tg) resulting from excessive addition of the constituent unit derived from a polyfunctional monomer of trifunctionality or higher functionality is also suppressed, and this is also effective in the prevention of a decrease in weather resistance.

˜Structural Moiety Derived from Terminal Blocking Agent˜

The polyester film of the present invention preferably further has a structural moiety derived from a terminal blocking agent selected from an oxazoline compound, a carbodiimide compound, or an epoxy compound. Meanwhile, the “structural moiety derived from a terminal blocking agent” refers to a structure in which a terminal blocking agent has reacted with the carboxylic acid of a polyester terminal and is bonded to the terminal.

When a terminal blocking agent is contained in the polyester film, the terminal blocking agent reacts with the carboxylic acid at a polyester terminal, and exists in a state of being bonded to the polyester terminal. Therefore, the amount of terminal COOH (AV value) can be stably and easily maintained at a desired value such as the preferred range described above. That is, hydrolysis of the polyester that is accelerated by terminal carboxylic acid is suppressed, and weather resistance can be maintained at a high level. Furthermore, since the terminal blocking agent is bonded to a polyester terminal, causing the terminal moiety of the molecular chain to become bulky, and the amount of fine surface asperities at the film surface increases, the anchor effect can be easily expressed, and the adhesion between the polyester film and a coating layer that is formed by being applied on the film is enhanced. Moreover, the terminal blocking agent is bulky, and polyester molecules are prevented from slipping through the free volumes and migrating. As a result, there is also an effect of suppressing thermal shrinkage associated with molecular migration.

Meanwhile, the terminal blocking agent is an additive which reacts with terminal carboxyl groups of a polyester and reduces the amount of carboxyl terminals of the polyester.

A single kind of the terminal blocking agent may be used alone, or two or more kinds may be used in combination.

The terminal blocking agent is preferably contained in an amount in the range of from 0.1% by mass to 5% by mass, more preferably from 0.3% by mass to 4% by mass, and even more preferably from 0.5% by mass to 2% by mass, relative to the mass of the polyester film.

When the content ratio of the terminal blocking agent in the polyester film is 0.1% by mass or more, the adhesion to a coating layer becomes satisfactory, and also, an enhancement of weather resistance caused by an AV decreasing effect can be achieved, while low thermal shrinkability can also be imparted. Furthermore, when the content ratio of the terminal blocking agent in the polyester film is 5% by mass or less, the adhesion to a coating layer becomes satisfactory, and also, a decrease in the glass transition temperature (Tg) of the polyester caused by addition of the terminal blocking agent is suppressed, so that a decrease in weather resistance or an increase in thermal shrinkage can be suppressed. This is because an increase in hydrolyzability that occurs as a result of a relative increase in the reactivity of the polyester caused by the decrease in Tg can be suppressed, or thermal shrinkage that occurs as a result of the likeliness of an increase in mobility of polyester molecules that increases with a decrease in Tg can be suppressed.

The terminal blocking agent according to the present invention is preferably a compound having a carbodiimide group, an epoxy group, or an oxazoline group. Specific examples of the terminal blocking agent suitably include carbodiimide compounds, epoxy compounds, and oxazoline compounds.

The carbodiimide compounds having a carbodiimide group include monofunctional carbodiimides and polyfunctional carbodiimides. Examples of the monofunctional carbodiimides include dicyclohexylcarbodiimide, diisopropylcarbodiimide, dimethylcarbodiimide, diisobutylcarbodiimide, dioctylcarbodiimide, t-butylisopropylcarbodiimide, diphenylcarbodiimide, di-t-butylcarbodiimide, and di-β-naphthylcarbodiimide. Preferred examples include dicyclohexylcarbodiimide and diisopropylcarbodiimide.

Furthermore, the polyfunctional carbodiimides are preferably polycarbodiimides having a degree of polymerization of 3 to 15. A polycarbodiimide generally has a repeating unit represented by formula: “—R—N═C═N—” or the like, wherein R represents a divalent linking group such as an alkylene or an arylene. Examples of such a repeating unit include 1,5-naphthalenecarbodiimide, 4,4′-diphenylmethanecarbodiimide, 4,4′-diphenyldimethylmethanecarbodiimide, 1,3-phenylenecarbodiimide, 2,4-tolylenecarbodiimide, 2,6-tolylenecarbodiimide, a mixture of 2,4-tolylenecarbodiimide and 2,6-tolylenecarbodiimide, hexamethylenecarbodiimide, cyclohexane-1,4-carbodiimide, xylylenecarbodiimide, isophoronecarbodiimide, dicyclohexylmethane-4,4′-carbodiimide, methylcyclohexanecarbodiimide, tetramethylxylylenecarbodiimide, 2,6-diisopropylphenylcarbodiimide, and 1,3,5-triisopropylbenzene-2,4-carbodiimide.

The carbodiimide compound is preferably a carbodiimide compound having high heat resistance from the viewpoint that the generation of an isocyanate-based gas caused by thermal decomposition is suppressed. In order to increase heat resistance, it is preferable that the molecular weight (degree of polymerization) be larger, and more preferably, it is preferable to provide a structure having high heat resistance at the ends of the carbodiimide compound. Furthermore, when the temperature at which a polyester raw material resin is melt extruded is lowered, the weather resistance enhancing effect and the thermal shrinkage reducing effect provided by the carbodiimide compound are more effectively obtained.

A polyester film using a carbodiimide compound is preferably such that the amount of an isocyanate-based gas generated when the polyester film is maintained at a temperature of 300° C. for 30 minutes is 0% to 0.02% by mass. When the amount of generation of an isocyanate-based gas is 0.02% by mass or less, air bubbles (voids) are not easily produced in the polyester film, and accordingly, sites of stress concentration are not easily formed. Therefore, destruction or detachment that is prone to occur in a polyester film can be prevented. Thereby, adhesion between adjacent materials becomes satisfactory.

Here, the isocyanate-based gas is a gas having an isocyanate group, and examples thereof include diisopropylphenyl isocyanate, 1,3,5-triisopropylphenyl diisocyanate, 2-amino-1,3,5-triisopropylphenyl-6-isocyanate, 4,4′-dicyclohexylmethane diisocyanate, isophorone diisocyanate, and cyclohexyl isocyanate.

Preferred examples of the epoxy compounds having an epoxy group include glycidyl ester compounds and glycidyl ether compounds.

Specific examples of the glycidyl ester compounds include benzoic acid glycidyl ester, t-Bu-benzoic acid glycidyl ester, P-toluic acid glycidyl ester, cyclohexanecarboxylic acid glycidyl ester, pelargonic acid glycidyl ester, stearic acid glycidyl ester, lauric acid glycidyl ester, palmitic acid glycidyl ester, behenic acid glycidyl ester, versatic acid glycidyl ester, oleic acid glycidyl ester, linoleic acid glycidyl ester, linoleic acid glycidyl ester, behenolic acid glycidyl ester, stearolic acid glycidyl ester, terephthalic acid diglycidyl ester, isophthalic acid diglycidyl ester, phthalic acid diglycidyl ester, naphthalenedicarboxylic acid diglycidyl ester, methylterephthalic acid diglycidyl ester, hexahydrophthalic acid diglycidyl ester, tetrahydrophthalic acid diglycidyl ester, cyclohexanedicarboxylic acid diglycidyl ester, adipic acid diglycidyl ester, succinic acid diglycidyl ester, sebacic acid diglycidyl ester, dodecanedioic acid diglycidyl ester, octadecanedicarboxylic acid diglycidyl ester, trimelltic acid triglycidyl ester, and pyromellietic acid tetraglycidyl ester.

Furthermore, specific examples of the glycidyl ether compounds include phenyl glycidyl ether, O-phenyl glycidyl ether, 1,4-bis(β,γ-epoxypropoxy)butane, 1,6-bis(β,γ-epoxypropoxy)hexane, 1,4-bis(β,γ-epoxypropoxy)benzene, 1-(β,γ-epoxypropoxy)-2-ethoxyethane, 1-(β,γ-epoxypropoxy)-2-benzyloxyethane, 2,2-bis[p-(β,γ-epoxypropoxy)phenyl]propane, and a bisglycidyl polyether obtainable by a reaction between bisphenol, such as 2,2-bis(4-hydroxyphenyl)propane or 2,2-bis(4-hydroxyphenyl)methane, and epichlorohydrin.

The oxazoline compound can be appropriately selected for use among compounds having oxazoline groups, but among them, a bisoxazoline compound is preferred.

Examples of the bisoxazoline compound include 2,2′-bis(2-oxazoline), 2,2′-bis(4-methyl-2-oxazoline), 2,2′-bis(4,4-dimethyl-2-oxazoline), 2,2′-bis(4-ethyl-2-oxazoline), 2,2′-bis(4,4′-diethyl-2-oxazoline), 2,2′-bis(4-propyl-2-oxazoline), 2,2′-bis(4-butyl-2-oxazoline), 2,2′-bis(4-hexyl-2-oxazoline), 2,2′-bis(4-phenyl-2-oxazoline), 2,2′-bis(4-cyclohexyl-2-oxazoline), 2,2′-bis(4-benzyl-2-oxazoline), 2,2′-p-phenylenebis(2-oxazoline), 2,2′-m-phenylenebis(2-oxazoline), 2,2′-o-phenylenebis(2-oxazoline), 2,2′-p-phenylenebis(4-methyl-2-oxazoline), 2,2′-p-phenylenebis(4,4-dimethyl-2-oxazoline), 2,2′-m-phenylenebis(4-methyl-2-oxazoline), 2,2′-m-phenylenebis(4,4-dimethyl-2-oxazoline), 2,2′-ethylenebis(2-oxazoline), 2,2′-tetramethylenebis(2-oxazoline), 2,2′-hexamethylenebis(2-oxazoline), 2,2′-octamethylenebis(2-oxazoline), 2,2′-decamethylenebis(2-oxazoline), 2,2′-ethylenebis(4-methyl-2-oxazoline), 2,2′-tetramethylenebis(4,4-dimethyl-2-oxazoline), 2,2′-9,9′-diphenoxyethanebis(2-oxazoline), 2,2′-cyclohexylenebis(2-oxazoline), and 2,2′-diphenylenebis(2-oxazoline). Among these, from the viewpoint of having satisfactory reactivity with polyesters and having a high weather resistance enhancing effect, 2,2′-bis(2-oxazoline) is most preferred.

The bisoxazoline compounds may be used singly to the extent that the effects of the present invention are not impaired, and two or more kinds may also be used in combination.

According to the present invention, the polyfunctional monomer of trifunctionality or higher functionality, and the terminal blocking agent, which have been described above or will be described below, may be respectively used singly, or it is also acceptable to use both of these in combination.

The polyester film of the present invention may be produced by any method as long as it is a method capable of satisfying the IV value, the pre-peak temperature, and the variation in the degree of crystallinity. In the present invention, for example, the polyester film can be produced most suitably by the method for producing a polyester film of the present invention that will be disclosed below.

Hereinafter, the method for producing a polyester film of the present invention will be specifically described.

<Method for Producing Polyester Film>

The method for producing a polyester film of the present invention is configured to include at least: a film molding step of molding a polyester film by melt extruding a polyester raw material resin into a sheet form, and cooling the resin on a casting drum; a longitudinal stretching step of longitudinally stretching the molded polyester film in the longitudinal direction; and a transverse stretching step of transversely stretching the polyester film after the longitudinal stretching in a width direction perpendicular to the longitudinal direction,

wherein the transverse stretching step is configured to include: a preheating step of preheating the polyester film after the longitudinal stretching to a temperature at which stretching can be carried out; a stretching step of transversely stretching the preheated polyester film by applying tension to the film in the width direction perpendicular to the longitudinal direction; a thermal fixing step of thermally fixing the polyester film after the longitudinal stretching and the transverse stretching have been carried out, by heating the polyester film so as to have a variation in the maximum reached film surface temperature in the width direction of from 0.5° C. to 5.0° C., while controlling the maximum reached film surface temperature of the polyester film in the range of from 160° C. to 210° C., to crystallize the polyester film; a thermal relaxation step of relaxing the tension of the thermally fixed polyester film by heating the polyester film; and a cooling step of cooling the polyester film after the thermal relaxation.

In the present invention, when a long polyester film that has been molded in a molding process and longitudinally stretched in the longitudinal direction is transversely stretched in a width direction that is perpendicular to the longitudinal direction, the polyester after the longitudinal stretching is preheated in advance and then transversely stretched. However, since the thermal fixing treatment that is carried out after the transverse stretching is carried out so as to heat and crystallize the polyester film that has been subjected to longitudinal stretching and transverse stretching, such that the variation of the maximum reached film surface temperature in the width direction is from 0.5° C. to 5.0° C., while the maximum reached film surface temperature of the polyester film is controlled in the range of from 160° C. to 210° C., the intrinsic viscosity of the polyester film is adjusted to 0.70 dL/g or greater, while the variation of the degree of crystallinity in the film width direction is suppressed to a low level. Therefore, the occurrence of damages on the film surface during the course of production is suppressed, and the hydrolysis resistance is increased.

The hydrolysis resistance of the polyester film (hereinafter, also simply referred to as film) is preferably achieved by applying tension to the film by stretching, and thereby arranging the polyester molecules in a state of being stretched in the length direction of the molecules. Here, stretching is generally carried out using apparatuses including rolls, clips and the like, such that while the film is conveyed, stretching in the conveyance direction of the film (longitudinal stretching) and stretching in a direction perpendicular to the conveyance direction (transverse stretching) are carried out. However, in regard to the transverse stretching, the stretching treatment is carried out by conveying the film sequentially to a preheating section that heats the film in advance before stretching; a stretching section that applies tension to the film in order to stretch the film; a thermal fixing section that heats the film while applying tension thereto; a thermal relaxation section that relaxes the tension of the film; and a cooling section that cools the film.

When transverse stretching is carried out and thereby tension is applied to the film, polyester molecules are stretched, and the hydrolysis resistance of the film is enhanced. On the other hand, since the distance between the molecular chains of the polyester molecules also increases at the time of stretching, the thermal shrinkage ratio in the width direction of the film tends to increase. However, in the case where the film has a relatively large size with a width of 1 m or more, if the maximum reached film surface temperature at the time of thermal fixing is adjusted in the range of from 160° C. to 210° C. for the hydrolysis resistance, the degree of crystallinity changes greatly, the thermal shrinkage ratio further increases, and the fluctuation variations thereof are also enlarged. However, when the IV value of the film that is finally obtained is increased to 0.70 or higher, crystallization is delayed, and the variation of the degree of crystallinity in the film width direction is suppressed to a low level. Thereby, hydrolysis resistance of the film increases. Furthermore, since a difference in looseness between the edge portions and the central portion in the width direction of the film is not likely to occur, the occurrence of wrinkles and scratches in the film is suppressed.

Furthermore, although the polyester film is thermally relaxed after transverse stretching, as the tension in the film is relaxed in the thermal relaxation section, the dimensional stability of the film can be enhanced. It is contemplated to be because the film shrinks, and the distance between molecular chains of the polyester molecules is decreased. In this case, the hydrolysis resistance tends to deteriorate, as the film is thermally relaxed and tension is released. However, it is speculated that if the intrinsic viscosity (IV) of the polyester film thus obtainable is 0.70 dL/g or greater, polyester molecules become larger, and the movement of the molecules is also slowed. Consequently, excellent hydrolysis resistance can be obtained.

In the present invention, as described above, a film to which tension has been applied is thermally fixed by heating such that the maximum reached film surface temperature at the film surface is 160° C. to 210° C. That is, as the film is heated at 160° C. to 210° C. while tension is applied to the film, crystallization can be achieved without causing the polyester molecules to shrink, and thus, the polyester molecules can be fixed to a certain extent in a stretched state. Thus, the hydrolysis resistance of the film can be enhanced. At this time, since the maximum reached film surface temperature is relatively low, such as 210° C. or lower, it is satisfactory in view of hydrolysis resistance. However, in this temperature range, the temperature dependency of the degree of crystallinity is high, and the variation in the degree of crystallinity in the film is likely to become large. As discussed above, when the IV value of the film that is finally obtained is increased to 0.70 or greater, crystallization can be delayed, and the variation in the degree of crystallinity in the film width direction is suppressed to a low level.

Hereinafter, the details of the method for producing a polyester film of the present invention will be described specifically with regard to the various processes of the film molding step, the longitudinal stretching step, and the transverse stretching step.

[Film Molding Step]

In the film molding step, a polyester raw material resin is melt extruded into a sheet form, the sheet is cooled on a casting drum, and thereby a polyester film is molded. In the present invention, a polyester film having an intrinsic viscosity (IV) of 0.70 dL/g or greater is suitably molded.

In regard to the method of melt extruding a polyester raw material resin, and the polyester raw material resin, there are no particular limitations as long as they are a method and a polyester by which the intrinsic viscosity of a polyester film obtainable by melt extruding a polyester raw material resin and cooling the extrusion product is 0.70 dL/g or greater. However, the intrinsic viscosity can be adjusted to a desired intrinsic viscosity by means of the catalyst, polymerization method, and the like that are used in the synthesis of the polyester raw material resin.

First, the polyester raw material resin will be explained.

(Polyester Raw Material Resin)

The polyester raw material resin is not particularly limited as long as the resin serves as a raw material of a polyester film and is a material containing a polyester, and the polyester raw material resin may also include a slurry of inorganic particles or organic particles in addition to a polyester. Furthermore, the polyester raw material resin may also include titanium element derived from a catalyst.

The kind of the polyester that is included in the polyester raw material resin is not particularly limited.

The polyester may be synthesized using a dicarboxylic acid component and a diol component, or a commercially available polyester may also be used.

In the case of synthesizing a polyester, for example, the polyester may be obtained by subjecting (A) a dicarboxylic acid component and (B) a diol component to an esterification reaction and/or a transesterification reaction by a well known method.

Examples of the (A) dicarboxylic acid component include dicarboxylic acids such as aliphatic dicarboxylic acids such as malonic acid, succinic acid, glutaric acid, adipic acid, suberic acid, sebacic acid, dodecanedioic acid, dimer acid, eicosanedioic acid, pimelic acid, azelaic acid, methylmalonic acid, and ethylmalonic acid; alicyclic dicarboxylic acids such as adamantanedicarboxylic acid, norbornenedicarboxylic acid, isosorbide, cyclohexanedicarboxylic acid, and decalindicarboxylic acid; aromatic dicarboxylic acids such as terephthalic acid, isophthalic acid, phthalic acid, 1,4-naphthalenedicarboxylic acid, 1,5-naphthalenedicarboxylic acid, 2,6-naphthalenedicarboxylic acid, 1,8-naphthalenedicarboxylic acid, 4,4′-diphenyldicarboxylic acid, 4,4′-diphenyl ether dicarboxylic acid, 5-sodium sulfoisophthalate, phenylindanedicarboxylic acid, anthracenedicarboxylic acid, phenanthrenedicarboxylic acid, and 9,9′-bis(4-carboxyphenyl)fluorenic acid; and ester derivatives thereof.

Examples of the (B) diol component include diol compounds such as aliphatic diols such as ethylene glycol, 1,2-propanediol, 1,3-propanediol, 1,4-butanediol, 1,2-butanediol, and 1,3-butanediol; alicyclic diols such as cyclohexanedimethanol, spiro glycol, and isosorbide; and aromatic diols such as bisphenol A, 1,3-benzenedimethanol, 1,4-benzenedimethanol, and 9,9′-bis(4-hydroxyphenyl)fluorine.

As the (A) dicarboxylic acid component, it is preferable if at least one of aromatic dicarboxylic acids is used. More preferably, the (A) dicarboxylic acid component contains an aromatic dicarboxylic acid as a main component among the dicarboxylic acid components. A dicarboxylic acid component other than an aromatic dicarboxylic acid may also be included. Such a dicarboxylic acid component is an ester derivative of an aromatic dicarboxylic acid or the like.

Meanwhile, the term “main component” means that the proportion of the aromatic dicarboxylic acid among the dicarboxylic acid components is 80% by mass or more.

Furthermore, it is preferable that at least one aliphatic diol be used as the (B) diol component. As the aliphatic diol, ethylene glycol may be included, and preferably, the diol component contains ethylene glycol as a main component.

Meanwhile, the main component means that the proportion of ethylene glycol among the diol components is 80% by mass or more.

The amount of use of the diol component (for example, ethylene glycol) is preferably in the range of 1.015 moles to 1.50 moles relative to 1 mole of the dicarboxylic acid component (particularly, the aromatic dicarboxylic acid (for example, terephthalic acid)) and optionally ester derivatives thereof. This amount of use is more preferably in the range of 1.02 moles to 1.30 moles, and even more preferably in the range of 1.025 moles to 1.10 moles. When the amount of use is in the range of 1.015 or more, the esterification reaction proceeds satisfactorily, and when the amount of use is in the range of 1.50 moles or less, for example, the side production of diethylene glycol caused by dimerization of ethylene glycol is suppressed, and many characteristics such as the melting point, glass transition temperature, crystallinity, heat resistance, hydrolysis resistance, and weather resistance can be maintained satisfactorily.

The polyester raw material resin according to the present invention preferably contains a polyfunctional monomer in which the sum total (a+b) of the number of a carboxylic group (a) and the number of a hydroxyl group (b) is 3 or greater, as a copolymerization component (constituent component of trifunctionality or higher functionality). The phrase “contains a polyfunctional monomer . . . as a copolymerization component (constituent component of trifunctionality or higher functionality)” means that the polyester raw material resin contains a constituent unit derived from a polyfunctional monomer.

Examples of the constituent unit derived from a polyfunctional monomer in which the sum total (a+b) of the number of a carboxylic group (a) and the number of a hydroxyl group (b) is 3 or greater, include the constituent units derived from carboxylic acids described below.

As examples of a carboxylic acid in which the number of a carboxylic group (a) is 3 or greater (polyfunctional monomer), examples of trifunctional aromatic carboxylic acids include trimesic acid, trimellitic acid, pyromellitic acid, naphthalenetricarboxylic acid, and anthracenetricarboxylic acid; and examples of trifunctional aliphatic carboxylic acids include methanetricarboxylic acid, ethanetricarboxylic acid, propanetricarboxylic acid, and butanetricarboxylic acid. Examples of tetrafunctional aromatic carboxylic acids include benzenetetracarboxylic acid, benzophenonetetracarboxylic acid, naphthalenetetracarboxylic acid, anthracenetetracarboxylic acid, and perylenetetracarboxylic acid; and examples of tetrafunctional aliphatic carboxylic acids include ethanetetracarboxylic acid, ethylenetetracarboxylic acid, butanetetracarboxylic acid, cyclopentanetetracarboxylic acid, cyclohexanetetracarboxylic acid, and adamantanetetracarboxylic acid. Examples of pentafunctional or higher-functional aromatic carboxylic acids include benzenepentacarboxylic acid, benzenehexacarboxylic acid, naphthalenepentacarboxylic acid, naphthalenehexacarboxylic acid, naphthaleneheptacarboxylic acid, naphthaleneoctacarboxylic acid, anthracenepentacarboxylic acid, anthracenehexacarboxylic acid, anthraceneheptacarboxylic acid, and anthraceneoctacarboxylic acid; and examples of pentafunctional or higher-functional aliphatic carboxylic acids include ethanepentacarboxylic acid, ethaneheptacarboxylic acid, butanepentacarboxylic acid, butaneheptacarboxylic acid, cyclopentanepentacarboxylic acid, cyclohexanepentacarboxylic acid, cyclohexanehexacarboxylic acid, adamantanepentacarboxylic acid, and adamantanehexacarboxylic acid.

In the present invention, ester derivatives and acid anhydrides thereof and the like may be mentioned as examples, but the present invention is not intended to be limited to these.

Furthermore, compounds obtained by adding an oxy acid such as 1-lactide, d-lactide or hydroxybenzoic acid, a derivative thereof, plural oxy acids linked together, and the like to the carboxy terminal of the carboxylic acids described above are also suitably used.

These may be used singly, or if necessary, plural kinds may also be used in combination.

As examples of the polyfunctional monomer in which the number of a hydroxyl group (b) is 3 or greater, examples of trifunctional aromatic compounds include trihydroxybenzene, trihydroxynaphthalene, trihydroxyanthracene, trihydroxychalcone, trihydroxyflavone, and trihydroxycoumarin; examples of trifunctional aliphatic alcohols include glycerin, trimethylolpropane, and propanetriol; and examples of tetrafunctional aliphatic alcohols include pentaerythritol. Furthermore, compounds obtained by adding diols to the hydroxyl group end of the above-described compounds are also preferably used.

These may be used singly, or if necessary, plural kinds may also be used in combination.

Furthermore, as another polyfunctional monomer other than those described above, an oxy acid which has both a hydroxyl group and a carboxylic group in one molecule and in which the sum total (a+b) of the number of a carboxylic group (a) and the number of a hydroxyl group (b) is 3 or greater, may also be used. Examples of such an oxy acid include hydroxyisophthalic acid, hydroxyterephthalic acid, dihydroxyterephthalic acid, and trihydroxyterephthalic acid.

Furthermore, compounds obtained by adding an oxy acid such as 1-lactide, d-lactide or hydroxybenzoic acid, a derivative thereof, plural oxy acids linked together, and the like to the carboxy terminal of these polyfunctional monomers are also suitably used.

These may be used singly, or if necessary, plural kinds may also be used in combination.

In regard to the polyester raw material resin according to the present invention, the content ratio of the constituent unit derived from a polyfunctional monomer in the polyester raw material resin is preferably from 0.005% by mole to 2.5% by mole, based on all the constituent units present in the polyester raw material resin. The content ratio of the constituent unit derived from a polyfunctional monomer is more preferably from 0.020% by mole to 1% by mole; even more preferably from 0.025% by mole to 1% by mole; still more preferably from 0.035% by mole to 0.5% by mole; particularly preferably from 0.05% by mole to 0.5% by mole; and most preferably from 0.1% by mole to 0.25% by mole.

When a constituent unit derived from a polyfunctional monomer of trifunctionality or higher functionality is present in the polyester raw material resin, as described above, in the case where a polyester film is finally molded, the functional groups that were not used in polycondensation are subjected to hydrogen bonding and covalent bonding with the components in a coating layer that is formed by being applied on the polyester film, and thereby the adhesiveness between the coating layer and the polyester film is maintained more satisfactorily, while the occurrence of detachment can be effectively prevented. Furthermore, a structure in which polyester molecular chains are branched from a constituent unit derived from a polyfunctional monomer of trifunctionality or higher functionality is obtained, and entanglement between polyester molecules can be promoted.

In the esterification reaction and/or transesterification reaction, a conventionally known reaction catalyst can be used. Examples of the reaction catalyst include alkali metal compounds, alkaline earth metal compounds, zinc compounds, lead compounds, manganese compounds, cobalt compounds, aluminum compounds, antimony compounds, titanium compounds, and phosphorus compounds. Usually, it is preferable to add an antimony compound, a germanium compound, or a titanium compound as a polymerization catalyst in any stage before the method for producing a polyester is completed. As such a method, for example, to take a germanium compound as an example, it is preferable to add the germanium compound directly as a powder.

For example, the esterification reaction process is carried out by polymerizing an aromatic dicarboxylic acid and an aliphatic diol in the presence of a catalyst containing titanium compounds. This esterification reaction process is configured to include a process of using, as the titanium compound which is a catalyst, an organic chelated titanium complex containing an organic acid as a ligand, and also, adding at least an organic chelated titanium complex, a magnesium compound, and a pentavalent phosphoric acid ester which does not have an aromatic ring as a substituent, in this order during the process.

First, prior to the addition of the magnesium compound and the phosphorus compound, the aromatic dicarboxylic acid and the aliphatic diol are mixed with a catalyst containing an organic chelated titanium complex. The titanium compound such as an organic chelated titanium complex has high catalytic activity even in an esterification reaction, and the esterification reaction can be carried out satisfactorily. At this time, the titanium compound may be added to a mixture of the dicarboxylic acid component and the diol component, or the dicarboxylic acid component (or the diol component) and the titanium compound may be mixed first, and then the mixture may be mixed with the diol component (or the dicarboxylic acid component). Furthermore, the dicarboxylic acid component, the diol component, and the titanium compound may also be simultaneously mixed. Regarding the mixing, there are no particular limitations on the method, and mixing can be carried out by a conventionally known method.

More preferred examples of the polyester include polyethylene terephthalate (PET) and polyethylene-2,6-naphthalate (PEN), and an even more preferred example is PET. Furthermore, PET is preferably polymerized by using one kind or two or more kinds selected from a germanium (Ge)-based catalyst, an antimony (Sb)-based catalyst, an aluminum (Al)-based catalyst and a titanium (Ti)-based catalyst, and more preferably a Ti-based catalyst.

The Ti-based catalyst has high reaction activity, and can lower the polymerization temperature. Therefore, thermal decomposition of the polyester occurring particularly during the polymerization reaction to generate COOH can be suppressed. That is, when a Ti-based catalyst is used, the amount of terminal carboxylic acid of the polyester that causes thermal decomposition can be reduced, and the formation of foreign materials can be suppressed. When the amount of terminal carboxylic acid of the polyester is reduced, after the production of a polyester film, thermal decomposition of the polyester film can be suppressed.

Examples of the Ti-based catalyst include oxides, hydroxides, alkoxides, carboxylates, carbonates, oxalates, organic chelated titanium complexes, and halides. Regarding the Ti-based catalyst, two or more kinds of titanium compounds may be used in combination to the extent that the effects of the present invention are not impaired.

Examples of the Ti-based catalyst include titanium alkoxides such as tetra-n-propyl titanate, tetra-i-propyl titanate, tetra-n-butyl titanate, tetra-n-butyl titanate tetramer, tetra-t-butyl titanate, tetracyclohexyl titanate, tetraphenyl titanate, and tetrabenzyl titanate; titanium oxides obtainable by hydrolysis of titanium alkoxides; titanium-silicon or zirconium complex oxides obtainable by hydrolysis of mixtures of titanium alkoxides and silicon alkoxides or zirconium alkoxides; titanium acetate, titanium oxalate, titanium potassium oxalate, titanium sodium oxalate, potassium titanate, sodium titanate, a mixture of titanic acid-aluminum hydroxide, titanium chloride, a mixture of titanium chloride-aluminum chloride, titanium acetylacetonate, and organic chelated titanium complexes employing an organic acid as a ligand.

On the occasion of polymerizing a polyester, it is preferable to perform polymerization using a titanium (Ti) compound as a catalyst in an amount in the range of, in terms of titanium element, from 1 ppm to 50 ppm, more preferably from 2 ppm to 30 ppm, and even more preferably from 3 ppm to 15 ppm. In this case, the polyester raw material resin contains titanium element in an amount of from 1 ppm to 50 ppm.

When the amount of titanium element contained in the polyester raw material resin is 1 ppm or more, the weight average molecular weight (Mw) of the polyester increases, and the polyester is not easily thermally decomposed. Therefore, foreign materials in the extruder are reduced. When the amount of titanium element contained in the polyester raw material resin is 50 ppm or less, the Ti-based catalyst is not likely to become a foreign material, and stretching unevenness is reduced at the time of stretching of the polyester sheet.

[Titanium Compound]

It is preferable that at least one organic chelated titanium complex which has an organic acid as a ligand be used as a titanium compound as a catalyst component. Examples of the organic acid include citric acid, lactic acid, trimellitic acid, and malic acid. Among them, an organic chelated complex which employs citric acid or a citric acid salt as a ligand is preferred.

For example, when a chelated titanium complex which employs citric acid as a ligand is used, there occurs less generation of foreign materials such as fine particles, and a polyester having satisfactory polymerization activity and color tone can be obtained as compared with the cases of using other titanium compounds. Furthermore, even when a citric acid chelated titanium complex is used, a polyester having satisfactory polymerization activity and color tone and having fewer terminal carboxyl groups can be obtained by a method of adding the titanium complex in the stage of esterification reaction, as compared with the case of adding the titanium complex after the esterification reaction. In this regard, it is speculated that titanium catalysts also have an effect of catalyzing an esterification reaction; that when a titanium catalyst is added in the stage of esterification, the oligomer acid value at the time of completion of the esterification reaction is decreased, and the subsequent polycondensation reaction is carried out more efficiently, and that a complex which employs citric acid as a ligand has higher hydrolysis resistance compared with titanium alkoxides and the like, and effectively functions as a catalyst for esterification and a polycondensation reaction while maintaining the original activity, without being hydrolyzed during the process of esterification reaction.

Furthermore, it is generally known that as the amount of terminal carboxyl groups is larger, the hydrolysis resistance is poorer. Thus, since the amount of terminal carboxyl groups is decreased by the addition method described above, an enhancement in the hydrolysis resistance is expected.

The citric acid chelated titanium complex is easily available as commercially marketed products such as, for example, VERTEC AC-420 manufactured by Johnson Matthey PLC.

The aromatic dicarboxylic acid and the aliphatic diol can be introduced by preparing a slurry containing these compounds, and continuously supplying this slurry to an esterification reaction process.

Furthermore, examples of titanium compounds other than organic chelated titanium complexes generally include oxides, hydroxides, alkoxides, carboxylates, carbonates, oxalates, and halides. If the effects of the present invention are not impaired, other titanium compounds may also be used in combination with organic chelated titanium complexes.

Examples of such titanium compounds include titanium alkoxides such as tetra-n-propyl titanate, tetra-i-propyl titanate, tetra-n-butyl titanate, tetra-n-butyl titanate tetramer, tetra-t-butyl titanate, tetracyclohexyl titanate, tetraphenyl titanate, and tetrabenzyl titanate; titanium oxides obtainable by hydrolysis of titanium alkoxides; titanium-silicon or zirconium complex oxides obtainable by hydrolysis of mixtures of titanium alkoxides and silicon alkoxides or zirconium alkoxides; titanium acetate, titanium oxalate, titanium potassium oxalate, titanium sodium oxalate, potassium titanate, sodium titanate, a mixture of titanic acid-aluminum hydroxide, titanium chloride, a mixture of titanium chloride-aluminum chloride, and titanium acetylacetonate.

In the present invention, it is preferable that an aromatic dicarboxylic acid and an aliphatic diol be polymerized in the presence of a catalyst containing titanium compounds, at least one kind of the titanium compounds being an organic chelated titanium complex which employs an organic acid as a ligand, and that the polyester be produced by a method for producing a polyester, which is configured to include an esterification reaction step including at least a process of adding an organic chelated titanium complex, a magnesium compound, and a pentavalent phosphoric acid ester which does not have an aromatic ring as a substituent, in this order; and a polycondensation step of producing a polycondensate by subjecting the esterification reaction product produced in the esterification reaction step to a polycondensation reaction.

In this case, in the process of the esterification reaction, by adopting a sequence of addition in which while an organic chelated titanium complex is allowed to be present as a titanium compound, a magnesium compound is added, and then a particular pentavalent phosphorus compound is added, the reaction activity of the titanium catalyst can be maintained at an appropriately high level, and while electrostatic application characteristics are imparted by magnesium, a decomposition reaction during polycondensation can be effectively suppressed. Therefore, consequently, a polyester which is less affected by coloration, has high electrostatic application characteristics, and also has improved yellowing properties when exposed to high temperature, may be obtained.

Thereby, a polyester which undergoes coloration at the time of polymerization and coloration at the time of subsequent melting and film formation at a reduced level, has a reduced yellow tint as compared with polyesters of conventional antimony (Sb) catalyst systems, exhibits a color tone and transparency comparable to polyesters of germanium-based catalyst systems, which have relatively high transparency, and exhibits excellent heat resistance, can be provided. Furthermore, a polyester exhibiting high transparency with a reduced yellow tint may be obtained without using a color tone adjusting material such as a cobalt compound or a coloring material.

This polyester can be utilized for applications which require a high level of transparency (for example, optical films and industrial lithography), and since it is not necessary to use highly expensive germanium-based catalysts, significant cost reduction can be attempted. In addition, since the incorporation of catalyst-attributed foreign materials that are likely to be produced in a Sb catalyst system is avoided, the occurrence of breakdown in the process of film formation or the occurrence of defective product quality is reduced, and cost reduction due to an increase in yield can also be attempted.

On the occasion of performing the esterification reaction, it is preferable to provide a process of adding an organic chelated titanium complex which is a titanium compound, and a magnesium compound and a pentavalent phosphorus compound as additives in this order. At this time, the esterification reaction is allowed to proceed in the presence of the organic chelated titanium complex, and subsequently, the addition of the magnesium compound can be initiated prior to the addition of the phosphorus compound.

[Phosphorus Compound]

As a pentavalent phosphorus compound, at least one kind of a pentavalent phosphoric acid ester which does not have an aromatic ring as a substituent is used. Examples thereof include phosphoric acid esters having a lower alkyl group having 2 or fewer carbon atoms as a substituent [(OR)₃—P═O; wherein R represents an alkyl group having 1 or 2 carbon atoms], and specifically, trimethyl phosphate and triethyl phosphate are particularly preferred.

The amount of addition of the phosphorus compound is preferably an amount in terms of P element in the range of from 50 ppm to 90 ppm. The amount of the phosphorus compound is more preferably an amount of from 60 ppm to 80 ppm, and even more preferably an amount of from 60 ppm to 75 ppm.

[Magnesium Compound]

When the polyester contains a magnesium compound, the electrostatic applicability of the polyester is enhanced. In this case, coloration easily occurs, but in the present invention, coloration is suppressed so that an excellent color tone and excellent heat resistance are obtained.

Examples of the magnesium compound include magnesium salts such as magnesium oxide, magnesium hydroxide, magnesium alkoxide, magnesium acetate, and magnesium carbonate. Among them, from the viewpoint of solubility in ethylene glycol, magnesium acetate is most preferred.

Regarding the amount of addition of the magnesium compound, in order to impart high electrostatic applicability, an amount in terms of Mg element of 50 ppm or more is preferred, and an amount in the range of from 50 ppm to 100 ppm is more preferred. The amount of addition of the magnesium compound is preferably an amount in the range of from 60 ppm to 90 ppm, and more preferably an amount in the range of from 70 ppm to 80 ppm, in view of imparting electrostatic applicability.

In the esterification reaction process, it is particularly preferable if melt polymerization is carried out by adding the titanium compound which is a catalyst component, and the magnesium compound and the phosphorus compound which are additives, such that the value Z calculated from the following formula (i) satisfies the following relationship formula (ii). Here, the P content is the amount of phosphorus derived from all the phosphorus compounds including the pentavalent phosphoric acid ester which does not have an aromatic ring, and the Ti content is the amount of titanium derived from all the Ti compounds including the organic chelated titanium complex. As such, when a combined use of a magnesium compound and a phosphorus compound is selected in a catalyst system including a titanium compound, and the time for addition and the proportions of addition of the compounds are controlled, a color tone with less yellow tint may be obtained, while the catalytic activity of the titanium compound is maintained at an appropriately high level. Also, heat resistance that does not easily induce yellow coloration even if the polyester is exposed to a high temperature at the time of the polymerization reaction or at the time of film formation thereafter (during melting), can be imparted to the polyester.

Z=5×(P content [ppm]/atomic weight of P)−2×(Mg content [ppm]/atomic weight of Mg)−4×(Ti content [ppm]/atomic weight of Ti) (i)

0≦Z≦+5.0 (ii)

Since the phosphorus compound not only acts on titanium but also interacts with the magnesium compound, this parameter serves as an index which quantitatively expresses the balance between the three components.

The formula (i) is a formula expressing the amount of phosphorus capable of acting on titanium, obtainable by subtracting the phosphorus fraction that acts on magnesium from the total amount of phosphorus capable of reacting. When the value of Z is positive, it can be said that it is a situation in which phosphorus that inhibits titanium is in excess, and when the value is negative, it can be said that it is a situation in which the amount of phosphorus required to inhibit titanium is insufficient. In regard to the reaction, since the respective single atoms of Ti, Mg and P are not of equal valencies, the respective mole numbers in the formula are weighted by multiplying by the valencies.

In the present invention, a polyester having excellent color tone and resistance to heat coloration can be obtained with a reaction activity required in the reaction using a titanium compound, a phosphorus compound, and a magnesium compound that are inexpensive and easily available and does not require special synthesis or the like.

In the above formula (ii), from the viewpoint of further increasing color tone and the resistance to heat coloration while maintaining polymerization reactivity, it is preferable that the relationship: +1.0≦Z≦+4.0 be satisfied, and it is more preferable that the relationship: +1.5≦Z≦+3.0 be satisfied.

A preferred embodiment according to the present invention may be an embodiment in which before the esterification reaction is completed, a chelated titanium complex which employs citric acid or a citric acid salt as a ligand is added in an amount in terms of Ti element of from 1 ppm to 30 ppm, to an aromatic dicarboxylic acid and an aliphatic diol, subsequently a magnesium salt of a weak acid is added thereto in an amount in terms of Mg element of from 60 ppm to 90 ppm (more preferably, from 70 ppm to 80 ppm) in the presence of the chelated titanium complex, and after the addition, a pentavalent phosphoric acid ester which does not have an aromatic ring as a substituent is further added thereto in an amount in terms of P element of from 60 ppm to 80 ppm (more preferably, from 65 ppm to 75 ppm).

In the above, an embodiment in which 70% by mass or more of the total addition amount of each of the chelated titanium complex (organic chelated titanium complex), the magnesium salt (magnesium compound), and the pentavalent phosphoric acid ester is added in the order described above, is preferred.

The esterification reaction can be carried out using a multi-stage apparatus in which at least two reactors are connected in series, under the conditions in which ethylene glycol is refluxed, while the water or alcohol produced by the reaction is removed from the system.

Furthermore, the esterification reaction described above may be carried out in a single stage, or may be carried out in divided multiple stages.

In the case of carrying out the esterification reaction in a single stage, the esterification reaction temperature is preferably 230° C. to 260° C., and more preferably 240° C. to 250° C.

In the case of carrying out the esterification reaction in multiple stages, the temperature of the esterification reaction in a first reaction tank is preferably 230° C. to 260° C., and more preferably 240° C. to 250° C., and the pressure is preferably 1.0 kg/cm² to 5.0 kg/cm², and more preferably 2.0 kg/cm² to 3.0 kg/cm². The temperature of the esterification reaction in a second reaction tank is preferably 230° C. to 260° C., and more preferably 245° C. to 255° C., and the pressure is 0.5 kg/cm² to 5.0 kg/cm², and more preferably 1.0 kg/cm² to 3.0 kg/cm². Furthermore, in the case of carrying out the esterification reaction in three or more stages, the conditions for the esterification reaction in intermediate stages are preferably set to conditions between the conditions for the first reaction tank and the conditions for the final reaction tank.

—Polycondensation—

Polycondensation produces a polycondensation product by subjecting the esterification reaction product that has been produced by the esterification reaction to a polycondensation reaction. The polycondensation reaction may be carried out in a single stage, or may also be carried out in divided multiple stages.

The esterification reaction product such as an oligomer produced by the esterification reaction is subsequently supplied to a polycondensation reaction. This polycondensation reaction can be suitably carried out by supplying the esterification reaction product to polycondensation reaction tanks of multiple stages.

For example, in regard to the polycondensation reaction conditions in the case of carrying out the reaction in reaction tanks of three stages, an embodiment in which the first reaction tank is at a reaction temperature of 255° C. to 280° C., and more preferably 265° C. to 275° C., and at a pressure of 100 torr to 10 torr (13.3×10⁻³ MPa to 1.3×10⁻³ MPa), and more preferably 50 torr to 20 torr (6.67×10⁻³ MPa to 2.67×10⁻³ MPa); the second reaction tank is at a reaction temperature of 265° C. to 285° C., and more preferably 270° C. to 280° C., and at a pressure of 20 torr to 1 torr (2.67×10⁻³ MPa to 1.33×10⁻⁴ MPa), and more preferably 10 torr to 3 torr (1.33×10⁻³ MPa to 4.0×10⁻⁴ MPa); and the third reaction tank in the final reaction tank is at a reaction temperature of 270° C. to 290° C., and more preferably 275° C. to 285° C., and at a pressure of 10 torr to 0.1 torr (1.33×10⁻³ MPa to 1.33×10⁻⁵ MPa), and more preferably 5 torr to 0.5 torr (6.67×10⁻⁴ MPa to 6.67×10⁻⁵ MPa), is preferred.

In the polyester synthesized as described above, additives such as a light stabilizer, an oxidation inhibitor, an ultraviolet absorber, a flame retardant, an easy lubricating agent (fine particles), a nucleating agent (crystallizing agent), and a crystallization inhibitor may be further incorporated.

The polyester which is a raw material of a polyester sheet is preferably in the form of solid state polymerized pellets.

When solid state polymerization is carried out after polymerization is carried out by an esterification reaction, the water content and degree of crystallinity of the polyester film, the acid value of the polyester, that is, the concentration of terminal carboxyl groups of the polyester (Acid Value; AV), and the intrinsic viscosity (IV) can be controlled.

In the present invention, from the viewpoint of hydrolysis resistance of the polyester film, the intrinsic viscosity (IV) of the polyester is adjusted to 0.70 dL/g or greater. The intrinsic viscosity (IV) of the polyester is preferably from 0.70 dL/g to 0.9 dL/g. If the IV is less than 0.70 dL/g, since the molecular movement of the polyester is not inhibited, crystallization is prone to occur. Furthermore, when the IV is 0.9 dL/g or less, thermal decomposition of the polyester caused by shear heating inside an extruder does not occur excessively, crystallization is suppressed, and the acid value (AV) can be suppressed to a low level. Above all, the IV is more preferably from 0.75 dL/g to 0.90 dL/g, even more preferably from 0.75 dL/g to 0.85 dL/g, and still more preferably from 0.78 dL/g to 0.85 dL/g.

Particularly, when a Ti catalyst is used in the esterification reaction, solid state polymerization is carried out, and the intrinsic viscosity (IV) of the polyester is adjusted to from 0.70 dL/g to 0.9 dL/g, crystallization of the polyester in the cooling step for the molten resin in the production process for a polyester sheet can be easily suppressed.

Therefore, the polyester that is a raw material of the polyester film that is applied to longitudinal stretching and transverse stretching preferably has an intrinsic viscosity of from 0.70 dL/g to 0.9 dL/g, and also preferably contains titanium atoms derived from a catalyst (Ti catalyst).

The intrinsic viscosity (IV) is a value obtained by dividing the specific viscosity (ηₛₚ=ηᵣ−1), which is calculated by subtracting 1 from the ratio ηᵣ of the solution viscosity (η) and the solvent viscosity (η₀) (=η/η₀; relative viscosity), by the concentration, and extrapolating the quotient to a state of a concentration value of zero. The IV can be obtained by dissolving a polyester in a 1,1,2,2-tetrachloroethane/phenol (=⅔ [mass ratio]) mixed solvent, and determining the value from the solution viscosity at 25° C., using an Ubbelohde viscometer.

In the solid state polymerization of the polyester, a polyester polymerized by the esterification reaction described above or a commercially available polyester, which has been molded into a small piece form such as a pellet form, may be used as a starting material.

The solid state polymerization of the polyester may be carried out by a continuous method (a method of filling a tower with the resin, allowing the resin to be slowly retained for a predetermined time while heating the resin, and then sequentially sending out the resin), or may be carried out by a batch method (a method of introducing the resin in a container, and heating the resin for a predetermined time).

The solid state polymerization is preferably carried out in a vacuum or in a nitrogen atmosphere.

The solid state polymerization temperature of the polyester is preferably from 150° C. to 250° C., more preferably from 170° C. to 240° C., and even more preferably from 180° C. to 230° C. When the temperature is in the range described above, it is preferable from the viewpoint that the acid value (AV) of the polyester is further reduced.

Furthermore, the solid state polymerization time is preferably from 1 hour to 100 hours, more preferably from 5 hours to 100 hours, even more preferably from 10 hours to 75 hours, and particularly preferably from 15 hours to 50 hours. When the solid state polymerization time is in the range described above, the acid value (AV) and the intrinsic viscosity (IV) of the polyester can be easily controlled to preferred ranges.

The temperature of the solid state polymerization is preferably from 170° C. to 240° C., more preferably from 180° C. to 230° C., and even more preferably from 190° C. to 220° C.

(Melt Extrusion)

In the film molding step according to the present invention, the polyester raw material resin obtainable as described above is melt extruded and cooled, and thereby a polyester film is molded.

Melt extrusion of the polyester raw material resin is carried out by, for example, heating the polyester raw material resin to a temperature higher than or equal to the melting point of the resin by using an extruder equipped with one or two or more screws, and melt kneading the resin by rotating the screws. The polyester raw material resin melts in the extruder by heating and kneading with the screws to become a melt. Furthermore, from the viewpoint of suppressing thermal decomposition (hydrolysis of the polyester) in the extruder, it is preferable to purge the interior of the extruder with nitrogen and then to carry out melt extrusion of the polyester raw material resin. The extruder is preferably a twin-screw extruder from the viewpoint that the kneading temperature is suppressed to a low temperature.

The molten polyester raw material resin (melt) passes through a gear pump, a filter and the like, and is extruded from an extrusion die. The extrusion die is also simply referred to as “die” [see JIS B8650:2006, a) Extrusion molding machine, No. 134].

In this case, the melt may be extruded in a single layer or may be extruded in multiple layers.

It is preferable that the polyester raw material resin contain a terminal blocking agent selected from an oxazoline compound, a carbodiimide compound, or an epoxy compound. In this case, in the film molding step, a polyester raw material resin in which a terminal blocking agent has been incorporated is melt kneaded, and the polyester raw material resin that has reacted with the terminal blocking agent at the time of melt kneading is melt extruded.

As a process of incorporating a terminal blocking agent into the polyester raw material resin is provided, weather resistance is enhanced, and thermal shrinkage can be suppressed to a low level. Furthermore, in the case of molding a polyester film, the terminal blocking agent is bonded to the polyester terminals, thereby causing the terminal moiety of the molecular chain to become bulky, and the amount of fine surface asperities of the film surface increases. Therefore, the anchoring effect can be easily exhibited, and the adhesion between the polyester film and a coating layer that is formed by being applied on the film is enhanced.

The time for adding the terminal blocking agent is not particularly limited as long as it is in the stage in which the terminal blocking agent is melt kneaded together with the polyester raw material resin in the course from the introduction of the raw material to the extrusion; however, it is preferable that the terminal blocking agent be added during the processes of introducing the raw material to the cylinder and sending the raw material to the vent port by the screw, and supplied to melt kneading together with the raw material resin. For example, the terminal blocking agent can be directly added to the raw material resin in the cylinder by providing a supply port for supplying the terminal blocking agent in between the raw material inlet port of the cylinder which performs melt kneading and the vent port. At this time, the terminal blocking agent may be added to a polyester raw material resin with which heating and kneading has been initiated but a molten state is not completely reached, or may be added to a polyester raw material resin in a molten state (melt).

The amount of the terminal blocking agent based on the polyester raw material resin is preferably from 0.1% by mass to 5% by mass relative to the total mass of the polyester raw material resin. A preferred amount of the terminal blocking agent based on the polyester raw material resin is from 0.3% by mass to 4% by mass, and more preferably from 0.5% by mass to 2% by mass.

When the content ratio of the terminal blocking agent is 0.1% by mass or more, an enhancement of weather resistance due to an AV decreasing effect can be achieved, and low thermal shrinkability and adhesiveness can be imparted. Furthermore, when the content ratio of the terminal blocking agent is 5% by mass or less, the adhesiveness is increased, and a decrease in the glass transition temperature (Tg) of the polyester caused by the addition of the terminal blocking agent is suppressed, and a decrease in weather resistance or an increase in thermal shrinkage associated therewith can be suppressed. This is because an increase in hydrolyzability that occurs as a result of a relative increase in the reactivity of polyester caused by the decrease in Tg is suppressed, or the thermal shrinkage that occurs as a result of the likeliness of the increase in the mobility of polyester molecules caused by a decrease in Tg is suppressed.

The terminal blocking agent according to the present invention is preferably a compound having a carbodiimide group, an epoxy group, or an oxazoline group. Suitable specific examples of the terminal blocking agent include carbodiimide compounds, epoxy compounds, and oxazoline compounds.

The details of the examples and preferred embodiments of the carbodiimide compounds, epoxy compounds, and oxazoline compounds are as described above in the section “Polyester film.”

The polyester resin can be molded into a film form by extruding the melt (polyester) from a die onto a casting drum (casting treatment).

The thickness of the film-like polyester molded product obtainable by a casting treatment is preferably 0.5 mm to 5 mm, more preferably 0.7 mm to 4.7 mm and even more preferably 0.8 mm to 4.6 mm.

When the thickness of the film-like polyester molded product is adjusted to 5 mm or less, cooling delay caused by thermal storage of the melt is avoided. Furthermore, when the thickness is adjusted to 0.5 mm or more, OH groups and COOH groups in the polyester are diffused inside the polyester during the processes from extrusion to cooling, and exposure at the polyester surface of the OH groups and COOH groups that cause the occurrence of hydrolysis is suppressed.

The means for cooling the melt that has been extruded from the extrusion die is not particularly limited, and the melt may be exposed to cool air, brought into contact with a casting drum (cooling casting drum), or exposed to sprayed water. The cooling means may be carried out singly, or two or more means may be carried in combination.

Among the cooling means described above, from the viewpoint of preventing oligomer adhesion to the sheet surface at the time of continuous operation, the cooling means is preferably at least one of cooling by means of cool air or cooling using a casting drum. Furthermore, it is particularly preferable to cool the melt that has been extruded from the extruder with cool air, and also to cool the melt by bringing the melt into contact with a casting drum.

Also, the polyester molded product that has been cooled by using a casting drum or the like, is peeled off from the cooling member such as a casting drum by using a peeling member such as a peeling roll.

[Longitudinal Stretching Step]

In the longitudinal stretching step of the present invention, the polyester film that has been molded in the film molding step is longitudinally stretched in the longitudinal direction.

Longitudinal stretching of the film can be carried out by, for example, applying tension between two or more pairs of nip rolls that are arranged in the conveyance direction of the film, while conveying the film in the longitudinal direction of the film through one pair of nip rolls that have the film interposed therebetween. Specifically, for example, when one pair of nip rolls A are provided on the upstream side of the conveyance direction of the film, and one pair of nip rolls B are provided on the downstream side, during conveying the film, the speed of rotation of the nip rolls B on the downstream side is made faster than the speed of rotation of the nip rolls A on the upstream side, and thereby, the film is stretched in the conveyance direction (MD; Machine Direction). Meanwhile, two or more pairs of nip rolls may be provided independently on each of the upstream side and the downstream side. Furthermore, longitudinal stretching of the polyester film may be carried out using a longitudinal stretching apparatus equipped with the nip rolls described above.

In the longitudinal stretching process, the longitudinal stretch ratio of the polyester film is preferably 2 to 5 times, more preferably 2.5 to 4.5 times, and even more preferably 2.8 to 4 times.

Also, the areal stretch ratio that is represented by the product of the longitudinal stretch ratio and the transverse stretch ratio, is preferably 6 times to 18 times, more preferably 8 times to 17.5 times, and even more preferably 10 times to 17 times, of the area of the polyester film before stretching.

The temperature at the time of longitudinal stretching of the polyester film (hereinafter, also referred to as “longitudinal stretching temperature”) is, when the glass transition temperature of the polyester film is designated as Tg, preferably from (Tg−20° C.) to (Tg+50° C.), more preferably from (Tg−10° C.) to (Tg+40° C.), and even more preferably from Tg° C. to (Tg+30° C.).

In addition, regarding the means for heating the polyester film, in the case of performing stretching by using rolls such as nip rolls, the polyester film that is in contact with the rolls can be heated by providing, inside the rolls, a heater or pipes through which a warm solvent can be caused to flow. Furthermore, even in the case where rolls are not used, the polyester film can be heated by blowing warm air to the polyester film, bringing the polyester film into contact with a heat source such as a heater, or causing the polyester film to pass through the vicinity of a heat source.

The method for producing a polyester film of the present invention includes a transverse stretching step that will be described below, apart from the longitudinal stretching step. Accordingly, in the method for producing a polyester film of the present invention, a polyester film is stretched at least biaxially in the longitudinal direction of the polyester film (conveyance direction, MD) and in a direction perpendicular to the longitudinal direction of the polyester film (TD; Transverse Direction). Stretching in the MD direction and the TD direction may be carried out at least once, respectively.

Meanwhile, the “direction (TD) perpendicular to the longitudinal direction (conveyance direction, MD) of the polyester film” means the direction which forms perpendicularity (90°) with the longitudinal direction of the polyester film (conveyance direction, MD), but also includes a direction in which the angle with respect to the longitudinal direction (that is, the conveyance direction) can be substantially regarded as 90° under mechanical error conditions (for example, the direction of (90°±5°) with respect to the MD direction).

The method for biaxially stretching may be any of a sequential biaxial stretching method of performing longitudinal stretching and transverse stretching separately, and a simultaneous biaxial stretching method of performing longitudinal stretching and transverse stretching simultaneously. Longitudinal stretching and transverse stretching may be each independently carried out two or more times, and the order of longitudinal stretching and transverse stretching does not matter. For example, embodiments of stretching include longitudinal stretching and then transverse stretching, longitudinal stretching and then transverse stretching and then longitudinal stretching, longitudinal stretching and then longitudinal stretching and then transverse stretching, and transverse stretching and then longitudinal stretching. Among others, longitudinal stretching and then transverse stretching is preferred.

[Transverse Stretching Step]

Next, the transverse stretching step according to the present invention will be described in detail.

The transverse stretching step according to the present invention is a process of transversely stretching a polyester film after longitudinal stretching, in the width direction that is perpendicular to the longitudinal direction. This transverse stretching is carried out by providing a preheating step of preheating the polyester film after longitudinal stretching to a temperature at which stretching can be carried out; a stretching step of transversely stretching the preheated polyester film by applying tension to the film in the width direction that is perpendicular to the longitudinal direction; a thermal fixing step of thermally fixing the polyester film after longitudinal stretching and transverse stretching have been carried out, by heating the polyester film so as to have a variation in the maximum reached film surface temperature in the width direction of from 0.5° C. to 5.0° C., while controlling the maximum reached film surface temperature of the polyester film in the range of from 160° C. to 210° C., to crystallize the polyester film; a thermal relaxation step of relaxing the tension of the thermally fixed polyester film by heating the polyester film; and a cooling step of cooling the polyester film after thermal relaxation.

In regard to the transverse stretching step according to the present invention, there are no limitations on the specific means as long as the polyester film is transversely stretched by the configuration described above; however, it is preferable to perform the step using a transverse stretching apparatus or a biaxial stretching machine, which are capable of the treatments of the various processes included in the configuration.

—Biaxial Stretching Machine—

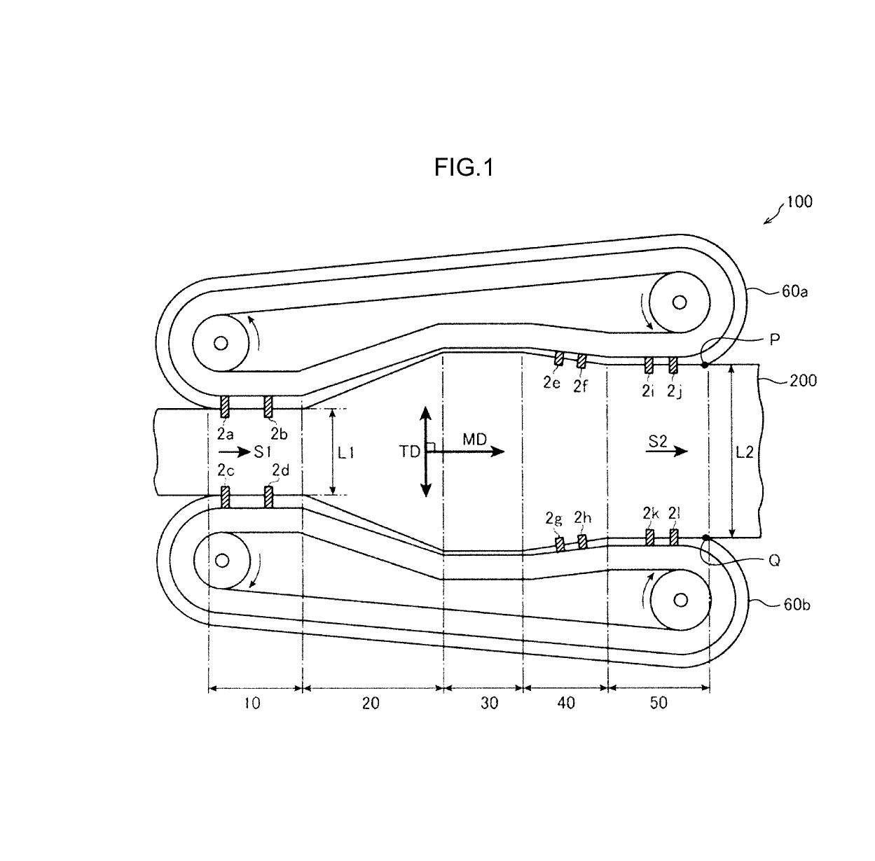

As shown in FIG. 1, a biaxial stretching machine 100 includes a pair of cyclic rails 60a and 60b; and gripping members 2a to 2l that are mounted on each of the cyclic rails and are capable of moving along the rail. The cyclic rails 60a and 60b are disposed symmetrically to each other, with the polyester film 200 being placed therebetween, and the polyester film 200 is gripped with the gripping members 2a to 2l and is allowed to move along the rails. Thereby, the polyester film can be stretched in the film width direction in this machine.

FIG. 1 is a top view showing an example of the biaxial stretching machine viewed from above.

The biaxial stretching machine 100 is configured to have regions including a preheating section 10 that preheats the polyester film 200; a stretching section 20 that stretches the polyester film 200 in the arrowed TD direction which is a direction perpendicular to the arrowed MD direction, and thereby applies tension to the polyester film; a thermal fixing section 30 that heats the polyester film to which tension has been applied, while tension is still applied; a thermal relaxation section 40 that heats the thermally fixed polyester film and thereby relaxes the tension of the thermally fixed polyester film; and a cooling section 50 that cools the polyester film that has passed through the thermal relaxation section.

The cyclic rail 60a is mounted with gripping members 2a, 2b, 2e, 2f, 2i and 2j that are capable of moving along the cyclic rail 60a, and the cyclic rail 60b is mounted with gripping members 2c, 2d, 2g, 2h, 2k and 2l that are capable of moving along the cyclic rail 60b. The gripping members 2a, 2b, 2e, 2f, 2i, and 2j grip one edge portion in the TD direction of the polyester film 200, and the gripping members 2c, 2d, 2g, 2h, 2k, and 2l grip the other edge portion in the TD direction of the polyester film 200. The gripping members 2a to 2l are generally referred to as chucks, clips, and the like. The gripping members 2a, 2b, 2e, 2f, 2i, and 2j move in a counterclockwise direction along the cyclic rail 60a, and the gripping members 2c, 2d, 2g, 2h, 2k, and 2l move in a clockwise direction along the cyclic rail 60b.

The gripping members 2a to 2d grip edge portions of the polyester film 200 in the preheating section 10, and while gripping the polyester film, the gripping members move along the cyclic rail 60a or 60b and progress through the stretching section 20 and the thermal relaxation section 40 at which the gripping members 2e to 2h are located, to the cooling section 50 where the gripping members 2i to 2l are located. Thereafter, in the order along the conveyance direction, the gripping members 2a and 2b, and the gripping members 2c and 2d separate from the edge portions of the polyester film 200 at the end of the downstream side in the MD direction of the cooling section 50, subsequently further move along the cyclic rail 60a or 60b, and return to the preheating section 10. At this time, the polyester film 200 moves in the arrowed MD direction and is sequentially supplied to the preheating step in the preheating section 10, the stretching step in the stretching section 20, the thermal fixing step in the thermal fixing section 30, the thermal relaxation step in the thermal relaxation section 40, and the cooling step in the cooling section 50, so that the polyester film is subjected to transverse stretching. The moving speed of the gripping members 2a to 2l in the various regions such as the preheating section is the conveyance speed of the polyester film 200.

The gripping members 2a to 2l can each independently have the moving speed varied.

The biaxial stretching machine 100 enables transverse stretching by which the polyester film 200 is stretched in the TD direction in the stretching section 20; however, by varying the moving speed of the gripping members 2a to 2l, the biaxial stretching machine can stretch the polyester film 200 also in the MD direction. That is, it is also possible to perform simultaneous biaxial stretching using the biaxial stretching machine 100.

For the gripping members that grip the edge portions in the TD direction of the polyester film 200, only the gripping members 2a to 2l are depicted in FIG. 1, but in order to support the polyester film 200, the biaxial stretching machine 100 is also equipped with gripping members that are not depicted, in addition to 2a to 2l. Meanwhile, in the following descriptions, the gripping members 2a to 2l may be collectively referred to as “gripping members 2”.

(Preheating Step)

In the preheating step, the polyester film after longitudinal stretching in the longitudinal stretching step is preheated to a temperature at which stretching can be carried out.

As shown in FIG. 1, the polyester film 200 is preheated in the preheating section 10. In the preheating section 10, the polyester film 200 is heated in advance before being stretched, so that transverse stretching of the polyester film 200 can be carried out easily.

The film surface temperature at the end point of the preheating section (hereinafter, also referred to as “preheating temperature”) is, when the glass transition temperature of the polyester film 200 is designated as Tg, preferably (Tg−10° C.) to (Tg+60° C.), and more preferably Tg° C. to (Tg+50° C.).

Meanwhile, the end point of the preheating section refers to the time point at which preheating of the polyester film 200 is completed, that is, the position at which the polyester film 200 is separated from the region of the preheating section 10.

(Stretching Step)

In the stretching step, the polyester film that has been preheated in the preheating step is transversely stretched by applying tension to the polyester film in the width direction (TD direction) perpendicular to the longitudinal direction (MD direction).

As illustrated in FIG. 1, in the stretching section 20, the preheated polyester film 200 is at least transversely stretched in the TD direction that is perpendicular to the longitudinal direction of the polyester film 200, and thereby tension is applied to the polyester film 200.

In the stretching section 20, the tension for transverse stretching (stretch tension) that is applied to the polyester film 200 is preferably 0.1 t/m to 6.0 t/m.

Furthermore, the areal stretch ratio (product of the respective stretch ratios) of the polyester film 200 is preferably 6 times to 18 times, more preferably 8 times to 17.5 times, and even more preferably 10 times to 17 times, of the area of the polyester film 200 before stretching.

Also, the film surface temperature at the time of transverse stretching (hereinafter, also referred to as “transverse stretching temperature”) of the polyester film 200 is, when the glass transition temperature of the polyester film 200 is designated as Tg, preferably from (Tg−10° C.) to (Tg+100° C.), more preferably from Tg° C. to (Tg+90° C.), and even more preferably from (Tg+10° C.) to (Tg+80° C.).

As described above, the gripping members 2a to 2l can each independently have the moving speed varied. Therefore, for example, by making the moving speed of the gripping members 2 that are on the downstream side in the MD direction of the stretching section 20, such as the stretching section 20 and the thermal fixing section 30, faster than the moving speed of the gripping members 2 in the preheating section 10, longitudinal stretching by which the polyester film 200 is stretched in the conveyance direction (MD direction) can also be carried out at the same time. Longitudinal stretching of the polyester film 200 in the transverse stretching step may be carried out only in the stretching section 20, or may also be carried out in the thermal fixing section 30, the thermal relaxation section 40, or the cooling section 50 that will be described below. Longitudinal stretching may also be carried out at plural sites.

(Thermal Fixing Step)

In the thermal fixing step, the polyester film after having been subjected to longitudinal stretching and transverse stretching is thermally fixed by crystallizing the polyester film by heating the polyester film so as to have a variation in the maximum reached film surface temperature in the width direction of from 0.5° C. to 5.0° C. while controlling the maximum reached film surface temperature in the range of from 160° C. to 210° C.

Thermal fixing means crystallizing the polyester film by heating the film at a particular temperature while maintaining the tension applied to the polyester film 200 in the stretching section 20.

In the thermal fixing section 30 shown in FIG. 1, with respect to the polyester film 200 to which tension is applied, the maximum reached film surface temperature (in the present specification, also referred to as “thermal fixing temperature”) at the surface of the polyester film 200 is controlled in the range of 160° C. to 210° C., and thereby heating is carried out. If the maximum reached film surface temperature is lower than 160° C., since polyesters hardly crystallize, polyester molecules cannot be fixed in a stretched state, and hydrolysis resistance cannot be increased. Furthermore, if the thermal fixing temperature is higher than 210° C., slipping occurs at the area where polyester molecules are entangled with each other, and polyester molecules shrink, so that hydrolysis resistance cannot be increased. In other words, when the polyester film is heated such that the maximum reached film surface temperature is 160° C. to 210° C., the crystals of polyester molecules can be oriented, and hydrolysis resistance can be increased.

For the reasons described above, the thermal fixing temperature is preferably in the range of 170° C. to 200° C., and more preferably in the range of 175° C. to 195° C.

Meanwhile, the maximum reached film surface temperature (thermal fixing temperature) is the value measured by bringing a thermocouple into contact with the surface of the polyester film 200.

When the maximum reached film surface temperature is controlled to 160° C. to 210° C. as described above, the variation of the maximum reached film surface temperature in the film width direction is adjusted to from 0.5° C. to 5.0° C. When the variation of the maximum reached film surface temperature of the film in the width direction is 0.5° C. or greater, it is advantageous in view of wrinkling at the time of conveyance in the subsequent steps, and when the variation is suppressed to be 5.0° C. or less, the variation in the degree of crystallinity in the width direction is suppressed. Thereby, the difference in looseness in the film width direction is reduced, and the occurrence of damages on the film surface in the production process is prevented, so that hydrolysis resistance can be increased.

Above all, for the reasons such as described above, the variation of the maximum reached film surface temperature is more preferably from 0.7° C. to 3.0° C., even more preferably from 0.8° C. to 2.0° C., and particularly preferably from 0.8° C. to 1.5° C.

Furthermore, heating of the film at the time of thermal fixing may be carried out only from one side of the film, or may be carried out from both sides. For example, when the polyester film is cooled on the casting drum after melt extrusion in the film molding step, since there is a difference between one surface and the other surface of the molded polyester film in terms of the cooling state, the film is prone to curl. Therefore, it is preferable to carry out the heating in this thermal fixing step on the surface that has been brought into contact with the casting drum in the film molding step. When the heated surface in the thermal fixing step is the surface that has been brought into contact with the casting drum, that is, the cooled surface, the problem of curling can be solved.

At this time, heating is preferably carried out such that the surface temperature of the heated surface immediately after heating in the thermal fixing step is higher than the surface temperature of the non-heated surface on the side opposite to the heated surface by from 0.5° C. to 5.0° C. When the temperature of the heated surface at the time of thermal fixing is higher than that of the surface on the opposite side, and the temperature difference between the front surface and the back surface is 0.5° C. to 5.0° C., the problem of curling of the film is more effectively solved. From the viewpoint of the effect of solving the problem of curling, the temperature difference between the heated surface and the non-heated surface on the opposite side is more preferably in the range of 0.7° C. to 3.0° C., and even more preferably from 0.8° C. to 2.0° C.

In the case of performing thermal fixing as described above, when the thickness of the polyester film is from 180 μm to 350 μm, the effect of solving the problem of curling is significant. If the film thickness is large, when a temperature change is applied to the film from one side of the film, a temperature distribution is prone to be formed in the film thickness direction, and curling is likely to occur. For example, when a polyester that has been melt extruded in the film molding step is brought into contact with a casting drum, while the film is cooled from one side, the surface on the opposite side is brought into contact with, for example, the atmosphere and thereby dissipates heat. However, since cooling of the one surface and cooling of the opposite surface proceed in different manners, a temperature difference is likely to occur. Therefore, when the thickness of the polyester film is 180 μm or more, since a temperature difference is prone to occur, the effect of solving the problem of curling is anticipated. Also, when the thickness is 350 μm or less, it is advantageous in that hydrolysis resistance is retained satisfactorily.

In regard to the film, the temperature of film edge portions is prone to decrease in the width direction that is perpendicular to the longitudinal direction of the film, because of the mounted clips and the like as described above, and a variation in temperature in the width direction, as well as a variation in the degree of crystallinity are likely to be brought about. Therefore, it is preferable to heat the edge portions in the width direction of the polyester film at the time of thermal fixing. Particularly, an embodiment of radiation heating using a radiation heater such as an infrared heater is more preferred. When radiation heating is carried out, the variation in temperature in the film width direction is preferably narrowed in the range of from 0.7° C. to 3.0° C., and thereby, the variation in the degree of crystallinity in the film width direction can be reduced in the range of from 0.5% to 3.0%. In this way, the difference in looseness in the width direction is reduced, the occurrence of damage is suppressed, and also, hydrolysis resistance can be further enhanced.

Furthermore, in the case of heating in the thermal fixing step, it is preferable to adjust the retention time in the thermal fixing section to from 5 seconds to 50 seconds. The retention time is a time period in which the state in which the film is heated in the thermal fixing section is continued. When the retention time is 5 seconds or longer, since the change in the degree of crystallinity against the heating time is decreased, it is advantageous in that the unevenness of the degree of crystallinity in the width direction is relatively difficult to occur. Also, when the retention time is 50 seconds or shorter, since it is not necessary to make the line speed of the tenter extremely small, it is advantageous in view of productivity.

Above all, for the reasons described above, the retention time is preferably from 8 seconds to 40 seconds, and more preferably from 10 seconds to 30 seconds.

The present invention may also be configured such that in at least one of the preheating step, stretching step or thermal relaxation step in addition to the thermal fixing step, the edge portions in the width direction of the polyester film are heated by radiation using a radiation heater such as an infrared heater. Heating at the edge portions in the width direction reduces the temperature variation in the width direction, and also the variation in the degree of crystallinity. Therefore, when heating is further carried out not only at the time of thermal fixing, but also in any one or two or more steps of preheating, stretching and thermal relaxation, a higher improving effect can be expected.

(Thermal Relaxation Step)

The thermal relaxation step heats the polyester film that has been fixed in the thermal fixing step, relaxes the tension of the polyester film, and eliminates residual strain. The dimensional stability of the film is enhanced, and if the IV value of the polyester film thus obtainable is 0.70 or greater, hydrolysis resistance can also be obtained.

In a preferred embodiment, the polyester film 200 is heated such that the maximum reached film surface temperature at the surface of the polyester film in the thermal relaxation section 40 shown in FIG. 1 is a temperature lower by 5° C. or more than the maximum reached film surface temperature (T_{thermal fixing}) of the polyester film 200 in the thermal fixing section 30.

Hereinafter, the maximum reached film surface temperature at the surface of the polyester film 200 at the time of thermal relaxation is also referred to as “thermal relaxation temperature (T_{thermal relaxation})”.

The dimensional stability of the polyester film can be further enhanced by heating, in the thermal relaxation section 40, the polyester film at a thermal relaxation temperature (T_{thermal relaxation}) which is a temperature lower by 5° C. or more than the thermal fixing temperature (T_{thermal fixing}) (T_{thermal relaxation}≦T_{thermal fixing}−5° C.), and thereby releasing the tension (making the stretch tension small).

When the T_{thermal relaxation} is lower than or equal to “T_{thermal fixing}−5“C”, the hydrolysis resistance of the polyester film is superior. Furthermore, the T_{thermal relaxation} is preferably 100° C. or higher from the viewpoint that the dimensional stability becomes satisfactory.

Furthermore, the T_{thermal relaxation} is preferably in a temperature region which is higher than or equal to 100° C. and is lower by 15° C. or more than the T_{thermal fixing} (100° C.≦T_{thermal relaxation}≦T_{thermal fixing}−15° C.); more preferably in a temperature region which is higher than or equal to 110° C. and is lower by 25° C. or more than the T_{thermal fixing} (110° C.≦T_{thermal relaxation}≦T_{thermal fixing}−25° C.); and particularly preferably in a temperature region which is higher than or equal to 120° C. and is lower by 30° C. or more than the T_{thermal fixing} (120° C.≦T_{thermal relaxation}≦T_{thermal fixing}−30° C.).

Meanwhile, the T_{thermal relaxation} is a value measured by bringing a thermocouple into contact with the surface of the polyester film 200.

In the thermal relaxation section 40, relaxation is carried out at least in the TD direction of the polyester film 200. Through such a treatment, the polyester film 200 to which tension has been applied, shrinks in the TD direction. Relaxation in the TD direction may be achieved by reducing the stretch tension applied to the polyester film 200 in the stretching section 20 by 2% to 90%. In the present invention, it is preferably 40%.

(Cooling Step)

In the cooling step, the polyester film after thermal relaxation in the thermal relaxation step is cooled.

As shown in FIG. 1, in the cooling section 50, the polyester film 200 that has gone through the thermal relaxation section 40 is cooled. As the polyester film 200 that has been heated in the thermal fixing section 30 and the thermal relaxation section 40 is cooled, the shape of the polyester film 200 is fixed.

The film surface temperature of the polyester 200 at the cooling section outlet in the cooling section 50 (hereinafter, also referred to as “cooling temperature”) is preferably lower than (the glass transition temperature Tg of the polyester film 200+50° C.). Specifically, the cooling temperature is preferably 25° C. to 110° C., more preferably 25° C. to 95° C., and even more preferably 25° C. to 80° C. When the cooling temperature is in the range described above, non-uniform shrinking of the film after being released from the clip gripping can be prevented.

Here, the cooling section outlet refers to the end of the cooling section 50 at the point where the polyester 200 departs from the cooling section 50, and refers to the position at which the gripping members 2 (in FIG. 1, gripping members 2j and 2l) that grip the polyester film 200 release the polyester film 200.

Meanwhile, during the preheating, stretching, thermal fixing, thermal relaxation, and cooling in the transverse stretching step, the temperature control means that heats or cools the polyester film 200 may be any means that blows warm air or cool air to the polyester film 200, brings the polyester film 200 into contact with the surface of a metal plate capable of temperature control, or passes the polyester film 200 through the vicinity of the aforementioned metal plate.

(Collection of Film)

For the polyester film 200 that has been cooled in the cooling step, the gripped portions, which have been gripped by clips, of both the edge portions in the TD direction are cut off, and the polyester film is rolled into a roll form.

In the transverse stretching step, in order to further increase the hydrolysis resistance and the dimensional stability of the polyester film thus produced, it is preferable to carry out relaxation of the stretched polyester film by the following technique.

In the present invention, it is preferable to perform the transverse stretching step after the longitudinal stretching step, and then to perform relaxation in the MD direction in the cooling section 50.

That is, in the preheating section 10, both the edge portions in the width direction (TD) of the polyester film 200 are gripped by using at least two gripping members at one of the edge portions. For example, one edge portion in the width direction (TD) of the polyester film 200 is gripped with gripping members 2a and 2b, and the other edge portion is gripped with gripping members 2c and 2d. Next, the polyester film 200 is conveyed from the preheating section 10 to the cooling section 50 by moving the gripping members 2a to 2d.

In such conveyance, the conveyance speed of the polyester film 200 is decreased by making the interval between the gripping member 2a (2c) that grips one edge portion in the width direction of the polyester film 200 and the other gripping member 2b (2d) that is adjacent to the gripping member 2a (2c) in the cooling section 50 narrower than the interval between the gripping member 2a (2c) that grips one edge portion in the width direction (TD direction) of the polyester film 200 and the other gripping member 2b (2d) that is adjacent to the gripping member 2a (2c) in the preheating section 10. By using such a technique, relaxation in the MD direction can be carried out in the cooling section 50.

Relaxation in the MD direction of the polyester film 200 can be carried out in at least a part of the thermal fixing section 30, the thermal relaxation section 40, and the cooling section 50.

As described above, relaxation in the MD direction of the polyester film 200 can be carried out by making the interval between the gripping members 2a and 2b and the interval between the gripping members 2c and 2d on the downstream side narrower than those on the upstream side in the MD direction. Therefore, in the case of carrying out relaxation in the MD direction in the thermal fixing section 30 or the thermal relaxation section 40, the interval between the gripping members 2a and 2b, and the interval between the gripping members 2c and 2d may be adjusted to be narrower than the intervals in the preheating section by reducing the moving speed of the gripping members 2a to 2d and thereby reducing the conveyance speed of the polyester film 200 when the gripping members 2a to 2d arrive at the thermal fixing section 30 or the thermal relaxation section 40.

As such, by achieving stretching in the TD direction (transverse stretching) and relaxation in the TD direction of the polyester film 200 in the transverse stretching step, and additionally achieving stretching in the MD direction (longitudinal stretching) and relaxation in the MD direction, dimensional stability can be improved while hydrolysis resistance is enhanced.

<Solar Cell Module>

A solar cell module is generally configured such that a solar cell device that converts the light energy of sunlight to electrical energy, is disposed between a transparent substrate through which sunlight enters and the polyester film of the present invention as described above (back sheet for a solar cell). According to a specific embodiment, the solar cell module may also be configured such that a power generating device (solar cell device) connected to a lead wire (not shown in the figure) that extracts electricity is sealed with a sealing agent such as an ethylene-vinyl acetate copolymer-based (EVA-based) resin, and this is interposed between a transparent substrate such as a glass plate and the polyester film (back sheet) of the present invention and adhered together.

As examples of the solar cell devices, various known solar cell devices can be applied, which include silicon types such as single crystalline silicon, polycrystalline silicon, and amorphous silicon; and Group III-V or Group II-VI compound semiconductor types such as copper-indium-gallium-selenium, copper-indium-selenium, cadmium-tellurium, and gallium-arsenic. The gap between the substrate and the polyester film may be sealed with, for example, a resin such as an ethylene-vinyl acetate copolymer (so-called sealing material).

### EXAMPLES

Hereinafter, the present invention will be more specifically described by way of Examples, but the present invention is not intended to be limited to the following Examples as long as the gist is maintained. Meanwhile, unless particularly stated otherwise, the unit “parts” is on a mass basis.

<Synthesis of Polyester Raw Material Resin>

(Polyester Raw Material Resin 1)

As described in the following, a polyester (Ti catalyst-based PET) was obtained by using a continuous polymerization apparatus and using a direct esterification method of allowing terephthalic acid and ethylene glycol to directly react with each other, distilling off water to achieve esterification, and performing polycondensation under reduced pressure.

(1) Esterification Reaction

To a first esterification reaction tank, 4.7 tons of high purity terephthalic acid and 1.8 tons of ethylene glycol were mixed over 90 minutes to form a slurry, and then the mixture was continuously supplied to a first esterification reaction tank at a flow rate of 3800 kg/h. Furthermore, an ethylene glycol solution of a citric acid chelated titanium complex in which citric acid is coordinated to Ti metal (VERTEC AC-420, manufactured by Johnson Matthey PLC) is continuously supplied thereto, and a reaction was carried out under stirring at a temperature inside the reaction tank of 250° C. for an average retention time of about 4.3 hours. At this time, the citric acid chelated titanium complex was continuously added such that the amount of Ti added would be 9 ppm in terms of the element. At this time, the acid value of the oligomer thus obtained was 600 equivalents/ton. Meanwhile, in the present specification, the unit “equivalents/ton” represents molar equivalents per ton.

This reaction product was transferred to a second esterification reaction tank, and the reaction product was allowed to react under stirring for an average retention time of 1.2 hours at a temperature in the reaction tank of 250° C. Thus, an oligomer having an acid value of 200 equivalents/ton was obtained. The second esterification reaction tank was divided in the inside into three zones, and an ethylene glycol solution of magnesium acetate was continuously supplied from the second zone such that the amount of Mg added would be 75 ppm in terms of the element. Subsequently, an ethylene glycol solution of trimethyl phosphate was continuously supplied from the third zone such that the amount of P added would be 65 ppm in terms of the element.

(2) Polycondensation Reaction

The esterification reaction product obtained as described above was continuously supplied to a first polycondensation reaction tank, and the reaction product was subjected to polycondensation under stirring for an average retention time of about 1.8 hours at a reaction temperature of 270° C. and a pressure inside the reaction tank of 20 torr (2.67×10⁻³ MPa).

Furthermore, the reaction product was transferred to a second polycondensation reaction tank, and in this reaction tank, the reaction product was allowed to react (polycondensation) under stirring for a retention time of about 1.2 hours at a temperature inside the reaction tank of 276° C. and a pressure inside the reaction tank of 5 torr (6.67×10⁻⁴ MPa).

Subsequently, the reaction product was further transferred to a third polycondensation reaction tank, and in this reaction tank, the reaction product was allowed to react (polycondensation) for a retention time of 1.5 hours at a temperature inside the reaction tank of 278° C. and a pressure inside the reaction tank of 1.5 torr (2.0×10⁻⁴ MPa). Thus, a reaction product (polyethylene terephthalate (PET)) was obtained.

Next, the reaction product thus obtained was discharged in a strand form into cold water and was immediately cut. Thereby, pellets <cross-section: major axis: about 4 mm, minor axis: about 2 mm, length: about 3 mm> of the polyester were produced.

The polyester thus obtained was analyzed as described below using high resolution type high frequency inductively coupled plasma-mass analysis (HR-ICP-MS; AttoM manufactured by SII Nanotechnology, Inc.), and the results were such that Ti=9 ppm, Mg=75 ppm, and P=60 ppm. P was slightly reduced relative to the initial amount of addition, and it is speculated that P had volatilized during the polymerization process.

The polymer thus obtained had an IV value of 0.65, an amount of terminal carboxyl groups (AV) of 22 equivalents/ton, a melting point of 257° C., and a solution haze of 0.3%. The measurement of the IV and AV was carried out by the methods described below.

(3) Solid State Polymerization Reaction

The pellets of the polyester obtained as described above were subjected to solid state polymerization by a batch method. That is, the pellets of the polyester were introduced into a container, and then while stirred in a vacuum, the pellets were subjected to preliminary crystallization at 150° C. Thereafter, a solid state polymerization reaction was carried out at 190° C. for 30 hours.

As described above, a polyester raw material resin 1 was synthesized.

(Polyester Raw Material Resin 2)

A polyester raw material resin 2 was obtained in the same manner as in the synthesis of the polyester raw material resin 1, except that the solid state polymerization time was changed from 30 hours to 12 hours.

(Polyester Raw Material Resin 3)

A polyester raw material resin 3 was obtained in the same manner as in the synthesis of the polyester raw material resin 1, except that the solid state polymerization time was changed from 30 hours to 10 hours.

### Example 1

<Production of Unstretched Polyester Film>

—Film Molding Step—

The polyester raw material resin 1 was dried to a water content of 20 ppm or less, and then was introduced into a hopper for a single-screw kneading extruder having a diameter of 50 mm. The polyester raw material resin 1 was melted at 300° C., and was extruded from a die via a gear pump and a filter (pore diameter: 20 μm) under the extrusion conditions described below. In addition, the slit dimension of the die was adjusted such that the thickness of the polyester sheet would be 4 mm. The thickness of the polyester sheet was measured with an automatic thickness meter provided at the outlet port of the casting drum.

At this time, extrusion of the molten resin was carried out under the conditions in which the pressure fluctuation was adjusted to 1%, and the temperature distribution of the molten resin was adjusted to 2%. Specifically, the back pressure in the barrel of the extruder was set to a pressure higher by 1% relative to the average pressure inside the barrel of the extruder, and heating was carried out at a piping temperature of the extruder higher by 2% relative to the average temperature inside barrel of the extruder. At the time of extruding the molten resin from a die, the molten resin was extruded onto a casting drum for cooling, and was adhered to the casting drum by using an electrostatic application method. Cooling of the molten resin was carried out such that the temperature of the casting drum was set to 25° C., and cold wind at 25° C. was blown from a cold air generating apparatus, which was installed to face the casting drum, to the molten resin. Using a peeling roll that was disposed to face the casting drum, an unstretched polyester film (unstretched polyester film 1) having a thickness of 3.5 mm and a film width of 0.7 m was peeled off from the casting drum.

The unstretched polyester film 1 thus obtained had an intrinsic viscosity IV of 0.80 dL/g, an amount of terminal carboxyl groups (AV) of 15 equivalents/ton, and a glass transition temperature (Tg) of 72° C.

˜Measurement of IV and AV˜

Regarding the intrinsic viscosity (IV), the unstretched polyester film 1 was dissolved in a 1,1,2,2-tetrachloroethane/phenol (=⅔ [mass ratio]) mixed solvent, and the intrinsic viscosity was determined from the viscosity of the solution at 25° C. in the mixed solvent.

Regarding the amount of terminal COOH (AV), the unstretched polyester film 1 was completely dissolved in a mixed solution of benzyl alcohol/chloroform (=⅔; volume ratio), and the solution was titrated with a reference liquid (0.025 N KOH-methanol mixed solution) using Phenol Red as an indicator. Thus, the amount of terminal COOH was calculated from the titer.

<Production of Biaxially Stretched Polyester Film>

The unstretched polyester film 1 thus obtained was stretched by performing biaxial stretching sequentially by the following method, and thus a biaxially stretched polyester film 1 having a thickness of 250 μm and a film width of 1.5 m was produced.

—Longitudinal Stretching Step—

The unstretched polyester film 1 was passed through two pairs of nip rolls having different circumferential speeds, and was stretched in the longitudinal direction (conveyance direction) under the conditions described below.

Preheating temperature: 80° C.

Longitudinal stretching temperature: 90° C.

Longitudinal stretch ratio: 3.6 times

Longitudinal stretch stress: 12 MPa

—Transverse Stretching Step—

The polyester film 1 that had been longitudinally stretched (longitudinally stretched polyester film 1) was stretched under the method and conditions described below, using a tenter (biaxial stretching machine) having the structure illustrated in FIG. 1.

(Preheating Section)

The preheating temperature was set to 110° C., and the polyester film was heated so that stretching could be carried out.

(Stretching Section)

The preheated longitudinally stretched polyester film 1 was transversely stretched by applying tension in the film width direction that was perpendicular to the longitudinal stretching direction (longitudinal direction) under the conditions described below.

<Conditions>
Stretching temperature (transverse stretching temperature): 120° C.
Stretch ratio (transverse stretch ratio): 4.4 times
Stretch stress (transverse stretch stress): 18 MPa

(Thermal Fixing Section)

Subsequently, the polyester film was heated such that the variation of the maximum reached film surface temperature in the width direction would be in the range described below by finely regulating the wind speed of hot air coming from hot air blowing nozzles while the maximum reached film surface temperature of the polyester film was controlled in the range described below, and thus the polyester film was crystallized. At this time, both the edge portions in the film width direction were heated by radiation with an infrared hater (heater surface temperature: 450° C.) from the cast surface side that was in contact with the casting drum in the film molding step.
Maximum reached film surface temperature (thermal fixing temperature T_{thermal fixing}): temperature indicated in the following Table 1 [° C.]
Variation of maximum reached film surface temperature (thermal fixing temperature T_{thermal fixing}): temperature indicated in the following Table 1 [° C.]

The thermal fixing temperature, T_{thermal fixing}, used herein is the pre-peak temperature [° C.] in DSC.

(Thermal Relaxation Section)

The polyester film after thermal fixing was heated to the temperature described below, and thereby tension of the film was relaxed. At this time, both the edge portions in the film width direction were heated by radiation with an infrared heater (heater surface temperature: 350° C.) from the cast surface side in the same manner as in the thermal fixing step.
Thermal relaxation temperature (T_{thermal relaxation}): 150° C.
Thermal relaxation ratio: TD direction (film width direction)=5%
   MD direction (direction perpendicular to the film width direction)=5%

(Cooling Section)

Next, the polyester film after thermal relaxation was cooled at a cooling temperature of 65° C.

—Collection of Film—

After completion of the cooling, a width of 20 cm was trimmed off in each of both the edge portions of the polyester film. Thereafter, press processing (knurling) was carried out over a width of 10 mm on both edge portions, and then the polyester film was rolled at a tension of 25 kg/m.

In the manner described above, a biaxially stretched polyester film (PET film) having a thickness of 250 μm was produced.

—A. Measurement and Evaluation—

The biaxially stretched polyester film produced as described above was subjected to measurement and evaluation as described below. The results for the measurement and evaluation are presented in the following Table 1.

(1) Variation of Thermal Shrinkage Ratio

The biaxially stretched polyester film was cut, and sample specimens M each having a size of 30 mm in the TD direction and 120 mm in the MD direction were obtained. In the sample specimens M, two reference lines were marked at an interval of 100 mm in the MD direction, and the sample specimens were left to stand for 30 minutes in a heating oven at 150° C. under no tension. After the standing, the sample specimens M were cooled to room temperature, and the distance between the two reference lines was measured for each sample piece. This value was designated as A mm, and the value of “100×(100−A)/100” was calculated. The value thus obtained was designated as thermal shrinkage ratio in the MD direction.

Furthermore, sample specimens L each having a size of 30 mm in the MD direction and 120 mm in the TD direction were obtained. In these sample specimens L, two reference lines were marked at an interval of 100 mm in the TD direction, and measurement and calculation were carried out in the same manner as in the case of the sample specimens M. The value thus obtained was designated as heating shrinkage in the TD direction.

The operation described above was carried out using specimens cut out from three sites in total, namely, one site in the central portion and two sites in both the edge portions, over the entire width of the film in the TD direction of the biaxially stretched polyester film, and the thermal shrinkage ratio of an edge portion which had a larger difference from the thermal shrinkage ratio of the central portion between the thermal shrinkage ratios of both the edge portions was subtracted from the thermal shrinkage ratio of the central portion. The absolute value of the difference was determined, and the absolute values obtained in the MD direction and the TD direction were designated as variations of thermal shrinkage ratio of the MD direction and the TD direction, respectively.

(2) Variation in Degree of Crystallinity

Specimens were cut out from three sites in total, namely, one site in the central portion and two sites in both the edge portions, over the entire film width of the biaxially stretched polyester film, and the degrees of crystallinity were measured. The variation in the degree of crystallinity was calculated by subtracting the degree of crystallinity of a smaller value between the degrees of crystallinity of both the edge portions from the degree of crystallinity of the central portion. At this time, the degree of crystallinity was calculated from the density of the film.

That is, the degree of crystallinity Xc (%) was derived by the following calculation formula by using the density X (g/cm³) of the film, the density Y (g/cm³) at a degree of crystallinity of 0%, and the density Z (g/cm³) at a degree of crystallinity of 100%. The measurement of density was carried out according to JIS K7112.

Xc={Z×(X−Y)}/{X×(Z−Y)}×100

(3) Measurement of Thickness

The thickness of the biaxially stretched polyester film thus obtained was determined as described below.

In the biaxially stretched polyester film, sampling was carried out from 50 sites at equal intervals over a length of 0.5 m in the longitudinally stretched direction (longitudinal direction), and sampling was carried out from 50 sites at equal intervals over the entire width of the film (50 equal divisions in the width direction) in the film width direction (direction perpendicular to the longitudinal direction). Subsequently, the thicknesses of these 100 sites were measured using a contact type film thickness meter (manufactured by Anritsu Corp.). The average thickness of these 100 sites was determined, and this was designated as the thickness of the polyester film. The thickness thus determined is indicated in the following Table 1.

(4) Damages and Wrinkles of Film

For the biaxially stretched polyester film thus obtained, the extent of damages and wrinkles on the film surface was visually observed and evaluated according to the evaluation criteria described below.

<Evaluation Criteria>

A: The occurrence of damages and wrinkles was hardly observed.

B: Slight occurrence of damages was observed, but the film surface was satisfactory.

C: The occurrence of both damages and wrinkles was observed, but at a level without any problem for practical use.

D: The occurrence of damages and wrinkles was conspicuously observed.

(5) Hydrolysis Resistance (Half-Life of Fracture Elongation)

The hydrolysis resistance of the biaxially stretched polyester film was evaluated from the half-life of fracture elongation of the biaxially stretched polyester film.

Specifically, the biaxially stretched polyester film was stored under the conditions of 120° C. and a relative humidity of 100%, and the storage time in which the fracture elongation (%) exhibited by the biaxially stretched polyester film after the storage became 50% of the fracture elongation (%) exhibited by the biaxially stretched polyester film before the storage, was designated as the half-life of fracture elongation. As the half-life of fracture elongation was longer, it meant that the hydrolysis resistance of the biaxially stretched polyester film was excellent.

Here, the fracture elongation (%) of the biaxially stretched polyester film was determined by pulling a sample specimen having a size of 1 cm×20 cm that was obtained by cutting the biaxially stretched polyester film, at a distance between chucks of 5 cm and at a rate of 20%/min.

<Evaluation Criteria>

A: The half-life of fracture elongation was longer than 90 hours.

B: The half-life of fracture elongation was longer than 85 hours and shorter than or equal to 90 hours.

C: The half-life of fracture elongation was longer than 80 hours and shorter than or equal to 85 hours.

D: The half-life of fracture elongation was shorter than 80 hours.

(6) Curling Properties

The biaxially stretched polyester film thus obtained was cut to sample specimens having a size of 300 mm in the TD direction and 300 mm in the MD direction, and each of these sample specimens was placed on a table in the direction in which the four corners rose up. The average of the heights of the four corners that had risen from the table was determined, and the average height was evaluated according to the evaluation criteria described below.

<Evaluation Criteria>

A: The average height was less than 3 mm, and the specimen was highly satisfactory.

B: The average height was greater than or equal to 3 mm and less than 10 mm, and the specimen was satisfactory.

C: The average height was greater than or equal to 10 mm and less than 20 mm, and the specimen was at a level without problem for practical use.

D: The average height was greater than 20 mm.

(7) Comprehensive Evaluation

The polyester film was evaluated from the evaluation results of the items (3) to (6) according to the criteria described below.

<Evaluation Criteria>

A: Highly satisfactory

B: Satisfactory

C: Not necessarily satisfactory, but at a level without problem for practical use

D: Causing a problem for practical use

Furthermore, a back sheet was produced as described below, using the biaxially stretched polyester film thus obtained.

<Formation of Reflective Layer>

—Preparation of Pigment Dispersion—

Components of the composition described below were mixed, and the mixture was subjected to a dispersion treatment for one hour using a Dyno Mill type dispersing machine. Thus, a pigment dispersion was prepared.

<Composition>

| | |
|---|---|
| Titanium dioxide (volume average particle size = | 39.9% by mass |
| 0.42 μm) (TIPAQUE R-780-2, manufactured by | |
| Ishihara Sangyo Kaisha, Ltd., solid content 100% by | |
| mass) | |
| Polyvinyl alcohol | 8.0% by mass |
| (PVA-105, manufactured by Kuraray Co., Ltd., | |
| solid content: 10% by mass) | |
| Surfactant | 0.5% by mass |
| (DEMOL EP, manufactured by Kao Corp., solid | |
| content: 25% by mass) | |
| Distilled water | 51.6% by mass |

—Preparation of Coating Liquid for Reflective Layer—

Components of the composition described below were mixed, and thus a coating liquid for reflective layer was prepared.

<Composition>

| | |
|---|---|
| Pigment dispersion described above | 80.0 parts |
| Aqueous dispersion liquid of polyacrylic resin | 19.2 parts |
| (Binder: JURYMER ET410, manufactured by | |
| Nihon Junyaku Co., Ltd., solid content: 30% by | |
| mass) | |
| Polyoxyalkylene alkyl ether | 3.0 parts |
| (NAROACTY CL95, manufactured by Sanyo | |
| Chemical Industries, Ltd., solid content: 1% by mass) | |
| Oxazoline compound (crosslinking agent) | 2.0 parts |
| (EPOCROS WS-700, manufactured by Nippon Shokubai | |
| Co., Ltd., solid content: 25% by mass) | |
| Distilled water | 7.8 parts |

—Formation of Reflective Layer—

The coating liquid for reflective layer thus obtained was applied on the biaxially stretched polyester film, and was dried for one minute at 180° C. Thus, a white layer (light reflective layer) having an amount of titanium dioxide of 6.5 g/m² was formed as a colored layer.

<Formation of Easy Adhesion Layer>

—Preparation of Coating Liquid for Easy Adhesion Layer—

Components of the composition described below were mixed, and thus a coating liquid for easy adhesion layer was prepared.

<Composition>

| | |
|---|---|
| Aqueous dispersion liquid of polyolefin resin | 5.2 parts |
| (Binder: CHEMIPEARL S-75N, manufactured by | |
| Mitsui Chemicals, Inc., solid content: 24% by mass) | |
| Polyoxyalkylene alkyl ether | 7.8 parts |
| (NAROACTY CL95, manufactured by Sanyo Chemical | |
| Industries, Ltd., solid content: 1% by mass) | |
| Oxazoline compound (crosslinking agent) | 0.8 parts |
| (EPOCROS WS-700, manufactured by Nippon | |
| Shokubai Co., Ltd., solid content: 25% by mass) | |
| Aqueous dispersion of silica fine particles | 2.9 parts |
| (AEROSIL OX-50, manufactured by Nippon | |
| Aerosil Co., Ltd., volume average particle size = | |
| 0.15 μm, solid content: 10% by mass) | |
| Distilled water | 83.3 parts |

—Formation of Easy Adhesion Layer—

The coating liquid thus obtained was applied on the light reflective layer such that the amount of the binder would be 0.09 g/m², and the coating liquid was dried for one minute at 180° C. Thus, an easy adhesion layer was formed.

<Back Layer>

—Preparation of Coating Liquid for Back Layer—

Components of the composition described below were mixed, and thus a coating liquid for back layer was prepared.

<Composition>

| | |
|---|---|
| CERANATE WSA-1070 (binder) | 323 parts |
| (Acrylic/silicone-based binder, manufactured by | |
| DIC Corp., solid content: 40% by mass) | |
| Oxazoline compound (crosslinking agent) | 52 parts |
| (EPOCROS WS-700, manufactured by Nippon | |
| Shokubai Co., Ltd., solid content: 25% by mass) | |
| Polyoxyalkylene alkyl ether (surfactant) | 32 parts |
| (NAROACTY CL95, manufactured by Sanyo | |
| Chemical Industries, Ltd., solid content: 1% by mass) | |
| Distilled water | 594 parts |

—Formation of Back Layer—

The coating liquid for back layer thus obtained was applied on the side of the biaxially stretched polyester film where the reflective layer and the easy adhesion layer were not formed, such that the amount of the binder would be 3.0 g/m² in terms of the wet coating amount. The coating liquid was dried for one minute at 180° C., and thus a back layer having a dried thickness of 3 μm was formed.

In the manner described above, a back sheet was produced.

—B. Evaluation—

The back sheet produced as described above was subjected to an adhesive evaluation as described below. The evaluation results are presented in the following Table 1.

(8) Adhesiveness

For the back sheet produced as described above, the adhesiveness between the base material and the coating layer was evaluated by the method described below.

(a) A sample was subjected to a wet heating treatment by which the sample was left to stand for 100 hours in an environment at 85° C. and 80% RH.

(b) The sample after the wet heating treatment was taken out, and 10 cuts at intervals of 3 mm were made in each of the length and width directions on the surface of the sample at the easy adhesion layer side, with a cutter knife, to produce 100 squares.

(c) The sample having squares produced thereon was immersed for one hour in warm water at 50° C., and then was taken out in a room in an environment at 25° C. and 60% RH. Water on the surface of the sample was wiped with a cloth. Thereafter, a tacky adhesive tape [a polyester tacky adhesive tape (No. 31B) manufactured by Nitto Denko Corp.] was attached on the surface of the sample where squares had been made. Subsequently, the tacky adhesive tape was peeled off at once in the direction of 180°. Meanwhile, this operation was carried out such that the time taken from the taking out from warm water to the peel-off of the tacky adhesive tape was within 5 minutes. That is, the evaluation of adhesiveness was to evaluate the adhesiveness of the coating layer of the sample in a wetted state.

(d) The surface of the sample where squares had been made was visually observed, and the number of the squares from which the coating layer was peeled off was counted. This number was designated as the “peeling ratio” and was used as an index for evaluating adhesiveness. The evaluation criteria were as follows.

<Evaluation Criteria>

A: The peeling ratio was less than 1%.

B: The peeling ratio was higher than or equal to 1% and less than 5%.

C: The peeling ratio was higher than or equal to 5% and less than 10%.

D: The peeling ratio was 10% or higher.

### Example 2

A biaxially stretched polyester film (PET film) having a thickness of 250 μm was produced in the same manner as in Example 1, except that the variation in the degree of crystallinity in the film width direction of the polyester film was changed from 0.8% to 2.2% by changing the solid state polymerization time from 30 hours to 12 hours, and thereby changing the IV of the polyester film from 0.80 to 0.75, in Example 1. A back sheet was further produced therefrom, and measurement and evaluation were carried out.

### Examples 3 and 4

Biaxially stretched polyester films (PET films) having a thickness of 250 μm were produced in the same manner as in Example 1, except that the thermal fixing temperature (T_{thermal fixing}; =DSC pre-peak temperature) during the thermal fixing step was replaced with 160° C. and 210° C. instead of 190° C., respectively, in Example 1. Back sheets were further produced therefrom, and measurement and evaluation were carried out.

### Example 5

A biaxially stretched polyester film (PET film) having a thickness of 250 μm was produced in the same manner as in Example 1, except that the variation in the degree of crystallinity in the film width direction of the polyester film was changed from 0.8% to 4.8% by not using the infrared heater used in the thermal fixing zone in Example 1. A back sheet was further produced therefrom, and measurement and evaluation were carried out.

### Examples 6 and 7

Biaxially stretched polyester films (PET films) were produced in the same manner as in Example 1, except that the thickness used in Example 1 was changed to the thickness indicated in the following Table 1, and the speed of rotation of the extruder was adjusted, to thereby change the thickness of the polyester film from 250 μm to 180 μm and 350 μm, respectively. Back sheets were further produced, and measurement and evaluation were carried out.

### Examples 8 and 9

Biaxially stretched polyester films (PET films) having a thickness of 250 μm were produced in the same manner as in Example 1, except that the retention time in the thermal fixing section where the thermal fixing step of the transverse stretching step was carried out in Example 1 was changed from 25 seconds to 5 seconds and 50 seconds, respectively. Back sheets were further produced, and measurement and evaluation were carried out.

### Examples 10 to 18

Biaxially stretched polyester films (PET films) having a thickness of 250 μm were produced in the same manner as in Example 1, except that in the “film molding step” of Example 1, the polyester raw material resin 1 was changed to polyester raw material resins 4 to 9 described below, with or without the terminal blocking material described in the following Table 1 being added to the polyester raw material resin that was melt kneaded, through the inlet port provided in the cylinder of the single-screw kneading extruder, after the polyester raw material resin was dried and introduced into a hopper. Back sheets were further produced, and also, measurement and evaluation were carried out.

(A) Synthesis of Polyester Raw Material Resins 4 to 6 and 8 to 9

Synthesis was carried out in the same manner as in the synthesis of the polyester raw material resin 1, except that in the “(1) Esterification reaction” in the synthesis of the polyester raw material resin 1, trimellitic acid (TMA; trifunctional carboxylic acid) was added at the proportion described in the following Table 1, in addition to terephthalic acid and ethylene glycol, and thereby copolymerization was carried out. Thus, polyester raw material resins 4 to 6 and 8 to 9 containing a constituent unit derived from a polyfunctional monomer were synthesized.

(B) Synthesis of Polyester Raw Material Resin 7

Synthesis was carried out in the same manner as in the synthesis of the polyester raw material resin 1, except that in the “(1) Esterification reaction” for the synthesis of the polyester raw material resin 1, benzenetetracarboxylic acid (BTC: tetrafunctional carboxylic acid) was added in addition to terephthalic acid and ethylene glycol, and thereby copolymerization was carried out. Thus, a polyester raw material resin 7 containing a constituent unit derived from a polyfunctional monomer was synthesized.

### Example 19

A biaxially stretched polyester film (PET film) having a thickness of 250 μm was produced in the same manner as in Example 1, except that the solid state polymerization time taken in Example 1 was changed from 30 hours to 9 hours to thereby change the IV of the polyester film to 0.71, the thermal fixing temperature (T_{thermal fixing}; =DSC pre-peak temperature) in the thermal fixing step was changed from 190° C. to 185° C., and the variation of the maximum reached film surface temperature in the film width direction was changed from 0.9° C. to 0.6° C. by increasing the wind speed of the hot air coming from hot air blowing nozzles of the thermal fixing section. A back sheet was further produced, and measurement and evaluation were carried out.

### Example 20

A biaxially stretched polyester film (PET film) having a thickness of 250 μm was produced in the same manner as in Example 10, except that the solid state polymerization time employed in Example 10 was changed from 30 hours to 9 hours to thereby change the IV of the polyester film to 0.71, the thermal fixing temperature (T_{thermal fixing}; =DSC pre-peak temperature) in the thermal fixing step was changed from 190° C. to 185° C., and the variation in the maximum reached film surface temperature in the film width direction was changed from 0.9° C. to 0.6° C. by increasing the wind speed of the hot air coming from hot air blowing nozzles of the thermal fixing section. A back sheet was further produced, and measurement and evaluation were carried out.

### Comparative Example 1

A biaxially stretched polyester film (PET film) having a thickness of 250 μm was produced in the same manner as in Example 1, except that the solid state polymerization time employed in Example 1 was changed from 30 hours to 10 hours, and thereby the IV of the polyester film was changed to 0.72. A back sheet was further produced, and measurement and evaluation were carried out.

### Comparative Examples 2 and 3

Biaxially stretched polyester film (PET films) having a thickness of 250 μm were produced in the same manner as in Example 1, except that the thermal fixing temperature (T_{thermal fixing}; =DSC pre-peak temperature) in the thermal fixing step employed in Example 1 was changed from 190° C. to 155° C. and 215° C. Back sheets were further produced, and measurement and evaluation were carried out.

### Comparative Example 4

A biaxially stretched polyester film (PET film) having a thickness of 250 μm was produced in the same manner as in Example 1, except that the use of an infrared heater that was used in the thermal fixing zone in Example 1 was canceled, and the variation in the degree of crystallinity in the film width direction of the polyester film was changed from 0.8% to 5.3% by decreasing the wind speed of hot air coming from hot air blowing nozzles. A back sheet was further produced, and measurement and evaluation were carried out.

### Comparative Example 5

A biaxially stretched polyester film (PET film) having a thickness of 250 μm was produced in the same manner as in Example 1, except that the surface temperature of the infrared heater used in the thermal fixing zone in Example 1 was changed from 450° C. to 600° C., and thereby the variation in the degree of crystallinity in the film width direction of the polyester film was changed from 0.8% to 0.1%. A back sheet was further produced, and measurement and evaluation were carried out.

### Comparative Example 6

A biaxially stretched polyester film (PET film) having a thickness of 250 μm was produced in the same manner as in Example 1, except that the solid state polymerization time employed in Example 1 was changed from 30 hours to 7 hours to thereby change the IV of the polyester film to 0.67, the thermal fixing temperature (T_{thermal fixing}; =DSC pre-peak temperature) in the thermal fixing step was changed from 190° C. to 200° C., and the variation in the maximum reached film surface temperature in the film width direction was changed from 0.9° C. to 3.4° C. by decreasing the wind speed of hot air coming from hot air blowing nozzles of the thermal fixing section. A back sheet was further produced, and measurement and evaluation were carried out.

TABLE 1

| | | | | | | Film properties | | | | | |
|---|---|---|---|---|---|---|---|---|---|---|---|
| | | | | | | | | | Thermal shrinkage ratio in width | | |
| | Polyester | | | | | | | Variation in | direction | | |
| | | Poly- | | | | | | degree of | MD | TD | |
| | | functional | | Terminal blocking | | | | crystallinity | Variation in | Variation in | |
| | Raw | monomer | | agent | | | DSC | in width | direction | direction parallel | Film |
| | material | | Content | | Content | | Pre-peak | direction | perpendicular to | to width | thickness |
| | resin | Kind | [mol %] | Kind | [%]*¹ | IV | [° C.] | [%] | width direction [%] | direction [%] | [μm] |
| Example 1 | Resin 1 | — | | — | | 0.80 | 190 | 0.8 | 0.08 | 0.08 | 250 |
| Example 2 | Resin 2 | — | | — | | 0.75 | 190 | 2.2 | 0.22 | 0.28 | 250 |
| Example 3 | Resin 1 | — | | — | | 0.80 | 160 | 0.8 | 0.44 | 0.42 | 250 |
| Example 4 | Resin 1 | — | | — | | 0.80 | 210 | 0.8 | 0.06 | 0.07 | 250 |
| Example 5 | Resin 1 | — | | — | | 0.80 | 190 | 4.8 | 0.45 | 0.46 | 250 |
| Example 6 | Resin 1 | — | | — | | 0.80 | 190 | 0.8 | 0.08 | 0.08 | 180 |
| Example 7 | Resin 1 | — | | — | | 0.80 | 190 | 0.8 | 0.08 | 0.08 | 350 |
| Example 8 | Resin 1 | — | | — | | 0.80 | 190 | 0.8 | 0.08 | 0.08 | 250 |
| Example 9 | Resin 1 | — | | — | | 0.80 | 190 | 0.8 | 0.08 | 0.08 | 250 |
| Example 10 | Resin 4 | TMA | 0.200 | CI | 1.00 | 0.80 | 190 | 0.8 | 0.08 | 0.08 | 250 |
| Example 11 | Resin 5 | TMA | 0.004 | CI | 1.00 | 0.80 | 190 | 0.8 | 0.08 | 0.08 | 250 |
| Example 12 | Resin 6 | TMA | 2.600 | CI | 1.00 | 0.80 | 190 | 0.8 | 0.08 | 0.08 | 250 |
| Example 13 | Resin 4 | TMA | 0.200 | — | | 0.80 | 190 | 0.8 | 0.08 | 0.08 | 250 |
| Example 14 | Resin 4 | TMA | 0.200 | CI | 5.50 | 0.80 | 190 | 0.8 | 0.08 | 0.08 | 250 |
| Example 15 | Resin 7 | BTC | 0.200 | EP | 1.00 | 0.80 | 190 | 0.8 | 0.08 | 0.08 | 250 |
| Example 16 | Resin 8 | TMA | 1.000 | CI | 1.00 | 0.80 | 190 | 0.8 | 0.08 | 0.08 | 250 |
| Example 17 | Resin 9 | TMA | 2.000 | CI | 1.00 | 0.80 | 190 | 0.8 | 0.08 | 0.08 | 250 |
| Example 18 | Resin 4 | TMA | 0.200 | Oxazoline | 1.00 | 0.80 | 190 | 0.8 | 0.08 | 0.08 | 250 |
| Example 19 | Resin 10 | — | | — | | 0.71 | 185 | 4.1 | 0.4 | 0.46 | 250 |
| Example 20 | Resin 11 | TMA | 0.200 | CI | 1.00 | 0.71 | 185 | 4.1 | 0.4 | 0.46 | 250 |

| | | | | | | | | | |
|---|---|---|---|---|---|---|---|---|---|
| Comparative | Resin 3 | — | — | 0.72 | 190 | 5.2 | 0.53 | 0.52 | 250 |
| Example 1 | | | | | | | | | |
| Comparative | Resin 1 | — | — | 0.80 | 155 | 0.8 | 0.54 | 0.55 | 250 |
| Example 2 | | | | | | | | | |
| Comparative | Resin 1 | — | — | 0.80 | 215 | 0.8 | 0.04 | 0.05 | 250 |
| Example 3 | | | | | | | | | |
| Comparative | Resin 1 | — | — | 0.80 | 190 | 5.3 | 0.55 | 0.56 | 250 |
| Example 4 | | | | | | | | | |
| Comparative | Resin 1 | — | — | 0.80 | 190 | 0.1 | 0.02 | 0.02 | 250 |
| Example 5 | | | | | | | | | |
| Comparative | Resin 12 | — | — | 0.67 | 200 | 5.8 | 0.56 | 0.58 | 250 |
| Example 6 | | | | | | | | | |

| | Transverse stretching step | | | | | Evaluation | | | | | |
|---|---|---|---|---|---|---|---|---|---|---|---|
| | Thermal fixing section | | | | | | Hydrolysis | | | | |
| | | | | Difference in | | | resistance | | | | |
| | | | Use or | temperature | | | 120° C. | | | | |
| | | Variation in | disuse of | between front | | | 100% rh | | | | |
| | | T_{thermal fixing} | radiation | and back (= cast | | Damages | Half-life of | | | | |
| | | in width | heater for | surface − surface | | and | fracture | | | | Compre- |
| | T_{thermal fixing} | direction | edge | opposite to cast | Retention | wrinkles in | elongation | | Film | Adhesive- | hensive |
| | [° C.] | [° C.] | portions | surface) [° C.] | time [s] | film | [hr] | | curling | ness | evaluation |
| Example 1 | 190 | 0.9 | Used | 1.2 | 25 | A | 105 | A | A | C | A |
| Example 2 | 190 | 0.9 | Used | 1.2 | 25 | B | 96 | A | A | C | B |
| Example 3 | 160 | 0.9 | Used | 1.2 | 25 | B | 105 | A | A | C | B |
| Example 4 | 210 | 0.9 | Used | 1.2 | 25 | A | 86 | B | A | C | B |
| Example 5 | 190 | 4.2 | Not used | 0.2 | 25 | B | 102 | A | C | C | B |
| Example 6 | 190 | 0.9 | Used | 0.5 | 25 | A | 103 | A | B | C | B |
| Example 7 | 190 | 0.9 | Used | 4.1 | 25 | A | 102 | A | B | C | B |
| Example 8 | 190 | 0.9 | Used | 1.2 | 5 | B | 104 | A | A | C | B |
| Example 9 | 190 | 0.9 | Used | 1.2 | 50 | A | 89 | B | A | C | B |
| Example 10 | 190 | 0.9 | Used | 1.2 | 25 | A | 105 | A | A | A | A |
| Example 11 | 190 | 0.9 | Used | 1.2 | 25 | A | 105 | A | A | B | A |
| Example 12 | 190 | 0.9 | Used | 1.2 | 25 | A | 105 | A | A | B | A |
| Example 13 | 190 | 0.9 | Used | 1.2 | 25 | A | 105 | A | A | B | A |
| Example 14 | 190 | 0.9 | Used | 1.2 | 25 | A | 105 | A | A | B | A |
| Example 15 | 190 | 0.9 | Used | 1.2 | 25 | A | 105 | A | A | A | A |
| Example 16 | 190 | 0.9 | Used | 1.2 | 25 | A | 105 | A | A | A | A |
| Example 17 | 190 | 0.9 | Used | 1.2 | 25 | A | 105 | A | A | B | A |
| Example 18 | 190 | 0.9 | Used | 1.2 | 25 | A | 105 | A | A | A | A |
| Example 19 | 185 | 0.6 | Used | 1.2 | 25 | B | 95 | A | A | C | B |
| Example 20 | 185 | 0.6 | Used | 1.2 | 25 | B | 105 | A | A | A | B |
| Comparative | 190 | 0.9 | Used | 1.2 | 25 | D | 88 | B | A | C | D |
| Example 1 | | | | | | | | | | | |
| Comparative | 155 | 0.9 | Used | 1.2 | 25 | D | 105 | A | A | C | D |
| Example 2 | | | | | | | | | | | |
| Comparative | 215 | 0.9 | Used | 1.2 | 25 | B | 78 | D | A | C | D |
| Example 3 | | | | | | | | | | | |
| Comparative | 190 | 5.5 | Not used | 0.2 | 25 | D | 102 | A | C | C | D |
| Example 4 | | | | | | | | | | | |
| Comparative | 190 | 0.4 | Used | 2.2 | 25 | D | 101 | A | B | C | D |
| Example 5 | | | | | | | | | | | |
| Comparative | 200 | 3.4 | Used | 1.2 | 25 | D | 79 | D | A | C | D |
| Example 6 | | | | | | | | | | | |

T_{thermal fixing}: thermal fixing temperature (maximum reached film surface temperature)
T_{thermal relaxation}: thermal relaxation temperature
*¹“%” represents a ratio with respect to a polyester raw material resin (polyester)

The details of the polyfunctional monomer and the terminal blocking material in the Table 1 are as follows.
TMA: Trimellitic acid (trifunctional carboxylic acid)
BTC: Benzenetetracarboxylic acid (tetrafunctional carboxylic acid)
CI: STABAXOL P100 (carbodiimide compound) manufactured by Rhein Chemie Rheinau GmbH
EP: CARDURA E10P (epoxy compound) manufactured by Hexion Specialty Chemicals, Inc.

As shown in the Table 1, in the Examples, the occurrence of damages or wrinkles occurring in the film is suppressed to a low level as compared with Comparative Examples, and the hydrolysis resistance was also satisfactory. Furthermore, by performing radiation heating from the film surface side that had been in contact with the casting drum for cooling in the film molding step, curling at the time of cooling with the casting drum was counterbalanced, so that PET films having more suppressed curling performance were obtained.

### Example 19

A reinforced glass plate having a thickness of 3 mm, an EVA sheet (SC50B manufactured by Mitsui Chemicals Fabro, Inc.), a crystalline solar cell, an EVA sheet (SC50B manufactured by Mitsui Chemicals Fabro, Inc.), and a back sheet produced in Examples 1 to 18 were superimposed in this order, and the assembly was hot pressed using a vacuum laminator (manufactured by Nisshinbo Holdings, Inc., a vacuum laminator) to adhere the members with EVA. Thus, a crystalline solar cell module was produced. At this time, the back sheet was disposed such that the easy adhesion layer was in contact with the EVA sheet, and adhesion was carried out by the method described below.

<Method for Adhesion>

Vacuuming was carried out for 3 minutes at 128° C. using a vacuum laminator, and then pressure was applied for 2 minutes to achieve provisional adhesion. Thereafter, a main adhesion treatment was applied in a dry oven at 150° C. for 30 minutes.

The solar cell modules produced as described above were operated for power generation, and they exhibited satisfactory power generation performance as solar cells.

All publications, patent applications, and technical standards mentioned in this specification are herein incorporated by reference to the same extent as if each individual publication, patent application, or technical standard was specifically and individually indicated to be incorporated by reference.

### INDUSTRIAL APPLICABILITY

The polyester film of the present invention can be suitably used for applications where excellent weather resistance is required, such as a protective sheet for a solar cell. Among others, the polyester film is suitable for applications such as a back surface protective sheet (so-called back sheet) that is disposed on the back surface on the side opposite to the sunlight-entering side of a solar cell power generating module, and a barrier film base material.

What is claimed is:

1. A biaxially stretched polyester film, having:
a film width of 1 m or more;
an intrinsic viscosity (IV) of 0.70 dL/g or greater;
a pre-peak temperature measured by differential scanning calorimetry (DSC) of from 160° C. to 210° C.; and
a variation in a degree of crystallinity in a film width direction of from 0.3% to 5.0%.

2. The biaxially stretched polyester film according to claim 1, having an intrinsic viscosity (IV) of 0.75 dL/g or greater.

3. The biaxially stretched polyester film according to claim 1, wherein a variation in a thermal shrinkage ratio A in the film width direction and a variation in a thermal shrinkage ratio B in the film width direction are respectively from 0.03% to 0.50%, and wherein the thermal shrinkage ratio A is a thermal shrinkage ratio in a direction perpendicular to the film width direction, and the thermal shrinkage ratio B is a thermal shrinkage ratio in a direction parallel to the film width direction.

4. The biaxially stretched polyester film according to claim 1, having a thickness of from 180 μm to 350 μm.

5. The biaxially stretched polyester film according to claim 1, comprising a constituent unit derived from a polyfunctional monomer in which a sum total of a number of a carboxylic group and a number of a hydroxyl group is 3 or greater.

6. The biaxially stretched polyester film according to claim 1, comprising a constituent unit derived from a polyfunctional monomer in which a sum total of a number of a carboxylic group and a number of a hydroxyl group is 3 or greater, wherein a content ratio of the constituent unit derived from the polyfunctional monomer is from 0.005% by mole to 2.5% by mole relative to all constituent units in the polyester.

7. The biaxially stretched polyester film according to claim 1, comprising a structural moiety derived from a terminal blocking agent selected from an oxazoline compound, a carbodiimide compound, or an epoxy compound.

8. The biaxially stretched polyester film according to claim 7, wherein a content ratio of the structural moiety derived from the terminal blocking agent is from 0.1% by mass to 5% by mass relative to a total mass of the polyester.

9. A method for producing a biaxially stretched polyester film, the method comprising:
molding a polyester film by melt extruding a polyester raw material resin into sheet form, and cooling the resin on a casting drum;
longitudinally stretching the molded polyester film in a longitudinal direction; and
transversely stretching the polyester film after the longitudinal stretching in a width direction perpendicular to the longitudinal direction,
wherein the transverse stretching comprises:
preheating the polyester film after the longitudinal stretching to a temperature at which stretching can be carried out;
transversely stretching the preheated polyester film by applying tension to the film in the width direction perpendicular to the longitudinal direction;
thermally fixing the polyester film after the longitudinal stretching and the transverse stretching have been carried out, by heating the polyester film so as to have a variation in a maximum film surface temperature in the width direction of from 0.5° C. to 5.0° C., while controlling the maximum film surface temperature of the polyester film in a range of from 160° C. to 210° C., to crystallize the polyester film;
relaxing a tension of the thermally fixed polyester film by heating the polyester film; and
cooling the polyester film after the relaxing.

10. The method for producing a biaxially stretched polyester film according to claim 9, wherein the thermal fixing comprises selectively heating edge portions in the width direction of the polyester film from at least one side of the polyester film.

11. The method for producing a biaxially stretched polyester film according to claim 9, wherein a thickness of the polyester film after the cooling is from 180 μm to 350 μm, and wherein the thermal fixing comprises heating the polyester film such that a heated surface of the polyester film that is heated is a surface that has been brought into contact with the casting drum in the molding, and a surface temperature of the heated surface immediately after the heating is higher than a surface temperature of a non-heated surface on a side opposite to the heated surface by from 0.5° C. to 5.0° C.

12. The method for producing a biaxially stretched polyester film according to claim 9, wherein the thermal fixing comprises radiation heating of edge portions in the width direction of the polyester film using a heater.

13. The method for producing a biaxially stretched polyester film according to claim 9, wherein in the thermal fixing, a retention time in a heated state is from 5 seconds to 50 seconds.

14. The method for producing a biaxially stretched polyester film according to claim 9, wherein at least one of the preheating, the transverse stretching of the preheated polyester film, or the relaxing comprises radiation heating of edge portions in the width direction of the polyester film using a heater.

15. The method for producing a biaxially stretched polyester film according to claim 9, wherein the polyester raw material resin contains, as a copolymerization component, a polyfunctional monomer in which a sum total of a number of a carboxylic group and a number of a hydroxyl group is 3 or greater.

16. The method for producing a biaxially stretched polyester film according to claim 9, wherein the polyester raw material resin contains, as a copolymerization component, a polyfunctional monomer in which a sum total of a number of a carboxylic group and a number of a hydroxyl group is 3 or greater, and a content ratio of a constituent unit derived from the polyfunctional monomer in the polyester raw material resin is from 0.005% by mole to 2.5% by mole relative to all constituent units in the polyester raw material resin.

17. The method for producing a biaxially stretched polyester film according to claim 9, wherein the molding comprises incorporating a terminal blocking agent selected from an oxazoline compound, a carbodiimide compound or an epoxy compound into the polyester raw material resin, and melt extruding the polyester raw material resin that has reacted with the terminal blocking agent as a result of melt kneading.

18. The method for producing a biaxially stretched polyester film according to claim 17, wherein a content of the terminal blocking agent is from 0.1% by mass to 5% by mass relative to a total mass of the polyester raw material resin.

19. A back sheet for a solar cell, comprising the biaxially stretched polyester film according to claim 1.

20. A solar cell module comprising: a transparent substrate through which sunlight enters; a solar cell device disposed on one side of the substrate; and the back sheet for a solar cell according to claim 19 that is disposed on a side of the solar cell device opposite to a side thereof on which the substrate is disposed.
